(19) United States
(12) Patent Application Publication
(10) Pub. No.: US 2025/0089505 A1
(43) Pub. Date: Mar. 13, 2025

(54) DISPLAY SUBSTRATE AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Fei FANG, Beijing (CN); Ling SHI, Beijing (CN); Changchang LIU, Beijing (CN); Haoyu LI, Beijing (CN); Yuxin ZHANG, Beijing (CN)

(21) Appl. No.: 18/727,345

(22) PCT Filed: May 11, 2023
(86) PCT No.: PCT/CN2023/093460

§ 371 Date: Jul. 9, 2024

(30) Foreign Application Priority Data
May 31, 2022 (CN) 202210615748.7

(51) Int. Cl. H10K 59/131; H10K 59/121; H10K 59/65

(52) U.S. Cl. CPC H10K 59/1315; H10K 59/1213; H10K 59/65

(57) ABSTRACT

A display substrate is provided, which includes a first display area (A1). The first display area (A1) includes a plurality of display island areas (A11), which are arranged in an array, and light-transmitting areas (A121, A122), which are located between adjacent display island areas (A11). The display island areas (All) each includes: a plurality of first pixel circuits (11) and a plurality of first light-emitting elements (13), which are provided on a base. At least one first pixel circuit (11) is electrically connected to at least one first light-emitting element (13) and is configured to drive the at least one first light-emitting element (13) to emit light. The first pixel circuits (11) in adjacent display island areas (A11) are connected by means of a plurality of first signal traces in a first direction (X).

### CROSS-REFERENCE TO RELATED APPLICATIONS

The present application is a U.S. National Phase Entry of International Application No. PCT/CN2023/093460 having an international filing date of May 11, 2023, which claims priority of Chinese Patent Application No. 202210615748.7, filed on May 31, 2022, to the China National Intellectual Property Administration, entitled “DISPLAY SUBSTRATE AND DISPLAY APPARATUS”. The above-identified applications are hereby incorporated by reference.

### TECHNICAL FIELD

The present disclosure relates to the field of display technologies, in particular to a display substrate and a display apparatus.

### BACKGROUND

An Organic Light Emitting Diode (OLED) and a Quantum dot Light Emitting Diode (QLED) are active light emitting display devices and have advantages of self-luminescence, a wide viewing angle, a high contrast ratio, low power consumption, an extremely high response speed, lightness and thinness, bendability, and a low cost, etc.

### SUMMARY

The following is a summary of subject matters described herein in detail. This summary is not intended to limit the protection scope of claims.

Embodiments of the present disclosure provide a display substrate and a display apparatus.

In one aspect, the embodiment provides a display substrate, including: a first display region, wherein the first display region includes a plurality of display island regions arranged in an array, and a light transmitting region located between adjacent display island regions. The display island region includes a plurality of first pixel circuits and a plurality of first light emitting elements disposed on a base substrate, at least one first pixel circuit of the plurality of first pixel circuits is electrically connected with at least one first light emitting element of the plurality of first light emitting elements, the at least one first pixel circuit is configured to drive the at least one first light emitting element to emit light. First pixel circuits in adjacent display island regions are connected in a first direction by a plurality of first signal lines, and the first pixel circuits in the adjacent display island regions are connected in a second direction by a plurality of second signal lines; the first direction intersects with the second direction; the material of the plurality of second signal lines includes a transparent conductive material, or the material of the plurality of first signal lines and the plurality of second signal lines each includes a metal material.

In some exemplary embodiments, a film on which the plurality of second signal lines are located is located on a side of a film on which the plurality of first signal lines are located away from the base substrate.

In some exemplary embodiments, the material of the plurality of first signal lines includes a metal material; the material of the plurality of second signal lines includes a transparent conductive material, and the plurality of second signal lines are of a structure of a same layer.

In some exemplary embodiments, at least portion of the plurality of second signal lines are located in the light transmitting region.

In some exemplary embodiments, the light transmitting region includes: a first light transmitting region located between display island regions adjacent along the second direction, and a second light transmitting region located between display island regions adjacent along the first direction; the area of the first light transmitting region is larger than the area of the second light transmitting region.

In some exemplary embodiments, the material of the plurality of first signal lines and the plurality of second signal lines each includes a metal material. The plurality of second signal lines are of a structure of a same layer, or at least one second signal line of the plurality of the second signal lines and the rest of the second signal lines are of structures of different layers.

In some exemplary embodiments, the light transmitting region includes at least: a first light transmitting region located between display island regions adjacent in the second direction; the display substrate further includes: a first line region located between adjacent first light transmitting regions, wherein the first line region is communicated with the display island region; the plurality of second signal lines are located in the first line region.

In some exemplary embodiments, the plurality of second signal lines includes a plurality of data connection lines for transmitting data signals to the plurality of first pixel circuits in the display island region, respectively, and at least one first power supply connection line for transmitting a first voltage signal to the plurality of first pixel circuits in the display island region.

In some exemplary embodiments, the plurality of first pixel circuits in the display island region are electrically connected to a same first power supply connection line.

In some exemplary embodiments, the plurality of first pixel circuits in the display island region are electrically connected to a plurality of first power supply connection lines, respectively, and the plurality of data connection lines and the plurality of first power supply connection lines are arranged at intervals.

In some exemplary embodiments, the plurality of first pixel circuits in the display island region are arranged sequentially along the first direction and a data connection line connected to a first one of the plurality of first pixel circuits and data connection lines connected to the rest of the first pixel circuits are of structures of different layers.

In some exemplary embodiments, at least one first signal line of the plurality of first signal lines and the rest of the first signal lines are of structures of different layers.

In some exemplary embodiments, the plurality of first signal lines includes: a first initial connection line for transmitting a first initial signal, a first scan connection line for transmitting a first scan signal, a second scan connection line for transmitting a second scan signal, and a light emitting control connection line for transmitting a light emitting control signal. The first scan connection line, the second scan connection line and the light emitting control connection line are of a structure of a same layer.

In some exemplary embodiments, at least one display island region of the plurality of display island regions includes three first pixel circuits and three first light emitting elements, the three first pixel circuits and the three first light emitting elements are electrically connected in one-to-one correspondence, the three first pixel circuits are sequentially arranged in the first direction.

In some exemplary embodiments, the three first light emitting elements include: a first light emitting element that emits light of a first color, a first light emitting element that emits light of a second color, and a first light emitting element that emits light of a third color. The first light emitting element emitting light of the first color and the first light emitting element emitting light of the second color are arranged in a same column, the first light emitting element emitting light of the third color and the first light emitting element emitting light of the first color are arranged in different columns, and the first light emitting element emitting light of the first color, the first light emitting element emitting light of the second color and the first light emitting element emitting light of the third color are arranged in different rows.

In some exemplary embodiments, an area of a light emitting region of the first light emitting element emitting light of the second color is larger than an area of a light emitting region of the first light emitting element emitting light of the first color, and an area of a light emitting region of the first light emitting element emitting light of the third color is larger than an area of the light emitting region of the first light emitting element emitting light of the first color.

In some exemplary embodiments, an orthographic projection of a light emitting region of the first light emitting element emitting light of the first color on the base substrate and an orthographic projection of a first pixel circuit to which the first light emitting element emitting light of the first color is connected on the base substrate at least partially overlap. An orthographic projection of a light emitting region of the first light emitting element emitting light of the second color on the base substrate and an orthographic projection of a first pixel circuit connected to the first light emitting element emitting light of the second color on the base substrate are not overlapped. An orthographic projection of a light emitting region of the first light emitting element emitting light of the third color on the base substrate overlaps at least partially with an orthographic projection of a first pixel circuit connected to the first light emitting element emitting light of the third color on the base substrate.

In some exemplary embodiments, an overlapping area of a light emitting region of the first light emitting element emitting light of the third color and a first pixel circuit connected to the first light emitting element emitting light of the third color is larger than an overlapping area of a light emitting region of the first light emitting element emitting light of the first color and a first pixel circuit connected to the first light emitting element emitting light of the first color.

In some exemplary embodiments, the display substrate further includes a second display region located on at least one side of the first display region; the second display region includes a plurality of second pixel circuits and a plurality of second light emitting elements disposed on the base substrate, at least one second pixel circuit of the plurality of second pixel circuits is electrically connected with at least one second light emitting element of the plurality of second light emitting elements, and the at least one second pixel circuit is configured to drive the at least one second light emitting element to emit light.

In another aspect, a display apparatus is provided in an embodiment of the present disclosure, which includes the aforementioned display substrate.

In another aspect, the present embodiment provides a display substrate including: a first display region. The first display region includes a plurality of display island regions arranged in an array, and a light transmitting region located between adjacent display island regions. The light transmitting region including a first light transmitting region located between display island regions adjacent in a second direction. At least one display island region of the plurality of display island regions and the first light transmitting region are alternately arranged in the second direction. The display island region includes a plurality of first pixel circuits and a plurality of first light emitting elements disposed on a base substrate. At least one first pixel circuit of the plurality of first pixel circuits is electrically connected with at least one first light emitting element of the plurality of first light emitting elements. At least one first pixel circuit is configured to drive the at least one first light emitting element to emit light. First pixel circuits in adjacent display island regions are connected by a plurality of first signal lines in a first direction, and the first pixel circuits in the adjacent display island regions are connected by a plurality of second signal lines in the second direction; the first direction intersects with the second direction.

In some exemplary embodiments, the first light transmitting region is located between the plurality of second signal lines in the first direction.

In some exemplary embodiments, the light transmitting region may include a second light transmitting region. The second light transmitting region is located between display island regions adjacent along the first direction. The area of the first light transmitting region may be larger than the area of the second light transmitting region.

In some exemplary embodiments, the second light transmitting region is located between the plurality of first signal lines.

In some exemplary embodiments, at least one display island region of the plurality of display island regions includes: three first pixel circuits and three first light emitting elements. The three first pixel circuits and the three first light emitting elements are electrically connected in one-to-one correspondence, the three first pixel circuits are sequentially arranged along the first direction. The three first light emitting elements include: a first light emitting element emitting light of a first color, a first light emitting element emitting light of a second color and a first light emitting element emitting light of a third color. An orthographic projection of a light emitting region of the first light emitting element emitting light of the first color on the base substrate and an orthographic projection of a first pixel circuit to which the first light emitting element emitting light of the first color is connected on the base substrate at least partially overlap. An orthographic projection of a light emitting region of the first light emitting element emitting light of the second color on the base substrate and an orthographic projection of a first pixel circuit connected to the first light emitting element emitting light of the second color on the base substrate are not overlapped. An orthographic projection of a light emitting region of the first light emitting element emitting light of the third color on the base substrate overlaps at least partially with an orthographic projection of a first pixel circuit connected to the first light emitting element emitting light of the third color on the base substrate.

Other aspects of the present disclosure may be comprehended after the drawings and the detailed descriptions are read and understood.

### BRIEF DESCRIPTION OF DRAWINGS

Accompanying drawings are used for providing further understanding of technical solutions of the present disclosure, constitute a part of the specification, and are used for explaining the technical solutions of the present disclosure together with embodiments of the present disclosure, but do not constitute limitations on the technical solutions of the present disclosure. Shapes and sizes of one or more components in the drawings do not reflect actual scales, and are only intended to schematically describe contents of the present disclosure.

FIG. 1 is a schematic diagram of a display substrate according to at least one embodiment of the present disclosure.

FIG. 2 is an equivalent circuit diagram of a pixel circuit according to at least one embodiment of the present disclosure.

FIG. 3 is a partial schematic diagram of a first display region according to at least one embodiment of the present disclosure.

FIG. 4 is a schematic diagram of an arrangement of a first pixel circuit and a first light emitting element in the first display region according to at least one embodiment of the present disclosure.

FIG. 5 is a schematic partial top view of region S1 in FIG. 4.

FIG. 6 is a schematic diagram of the display substrate after a semiconductor layer is formed in FIG. 5.

FIG. 7A is a schematic diagram of the display substrate after a first conductive layer is formed in FIG. 5.

FIG. 7B is a schematic diagram of the first conductive layer in FIG. 7A.

FIG. 8A is a schematic diagram of the display substrate after a second conductive layer is formed in FIG. 5.

FIG. 8B is a schematic diagram of the second conductive layer in FIG. 8A.

FIG. 9 is a schematic diagram of the display substrate after a third insulation layer is formed in FIG. 5.

FIG. 10A is a schematic diagram of the display substrate after a third conductive layer is formed in FIG. 5.

FIG. 10B is a schematic diagram of the third conductive layer in FIG. 10A.

FIG. 11 is a schematic diagram of the display substrate after a fourth insulating layer is formed in FIG. 5;

FIG. 12A is a schematic diagram of the display substrate after a transparent conductive layer is formed in FIG. 5;

FIG. 12B is a schematic diagram of the transparent conductive layer in FIG. 12A;

FIG. 13 is a schematic diagram of a display substrate after a fifth insulation layer is formed in FIG. 5.

FIG. 14A is a schematic diagram of the display substrate after a fourth conductive layer is formed in FIG. 5.

FIG. 14B is a schematic diagram of the fourth conductive layer in FIG. 14A.

FIG. 15 is a schematic diagram of a display substrate after a sixth insulation layer is formed in FIG. 5.

FIG. 16A is a schematic diagram of the display substrate after an anode layer is formed in FIG. 5.

FIG. 16B is a schematic diagram of the anode layer in FIG. 16A.

FIG. 17A is another schematic diagram of a first display region according to at least one embodiment of the present disclosure.

FIG. 17B is another schematic diagram of a first display region according to at least one embodiment of the present disclosure.

FIG. 17C is another schematic diagram of a first display region according to at least one embodiment of the present disclosure.

FIG. 18 is a schematic partial top view of the region S2 in FIG. 17A;

FIG. 19 is a schematic diagram of the display substrate after a first conductive layer is formed in FIG. 18;

FIG. 20 is a schematic diagram of the display substrate after a second conductive layer is formed in FIG. 18;

FIG. 21A is a schematic diagram of the display substrate after a third conductive layer is formed in FIG. 18.

FIG. 21B is a schematic diagram of the third conductive layer in FIG. 21A.

FIG. 22 is a schematic diagram of a display substrate after a fifth insulation layer is formed in FIG. 18.

FIG. 23A is a schematic diagram of the display substrate after a fourth conductive layer is formed in FIG. 18.

FIG. 23B is a schematic diagram of the fourth conductive layer in FIG. 23A.

FIG. 24 is a schematic diagram of a display substrate after a sixth insulation layer is formed in FIG. 18.

FIG. 25 is a schematic diagram of the display substrate after an anode layer is formed in FIG. 18.

FIG. 26 is another schematic partial top view of the region S2 in FIG. 17A;

FIG. 27 is a schematic diagram of the display substrate after a second conductive layer is formed in FIG. 26;

FIG. 28A is a schematic diagram of the display substrate after a third conductive layer is formed in FIG. 26.

FIG. 28B is a schematic diagram of the third conductive layer in FIG. 28A.

FIG. 29 is a schematic diagram of a display substrate after a fifth insulation layer is formed in FIG. 26.

FIG. 30A is a schematic diagram of a display substrate after a fourth conductive layer is formed in FIG. 26.

FIG. 30B is a schematic diagram of the fourth conductive layer in FIG. 30A.

FIG. 31 is a schematic diagram of a display device according to at least one embodiment of the present disclosure.

### DETAILED DESCRIPTION

The embodiments of the present disclosure will be described below with reference to the drawings in detail. Embodiments may be implemented in a plurality of different forms. Those of ordinary skills in the art may easily understand such a fact that implementations and contents may be transformed into other forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

In the drawings, a size of one or more constituent elements, a thickness of a layer, or a region is sometimes exaggerated for clarity. Therefore, one implementation of the present disclosure is not necessarily limited to the size, and a shape and a size of one or more components in the drawings do not reflect an actual scale. In addition, the accompanying drawings schematically illustrate ideal examples, and an implementation of the present disclosure is not limited to shapes, numerical values, or the like shown in the drawings.

Ordinal numerals “first”, “second”, “third”, etc., in the specification are set not to form limits in numbers but only to avoid confusion between composition elements. In the present disclosure, “plurality” represents two or more than two.

In the specification, for convenience, expressions “central”, “above”, “below”, “front”, “back”, “vertical”, “horizontal”, “top”, “bottom”, “inside”, “outside”, etc., indicating orientation or positional relationships are used to illustrate positional relationships between the composition elements with respect to the drawings, not to indicate or imply that involved devices or elements are required to have specific orientations and be structured and operated with the specific orientations but only to easily and simply describe the present specification, and thus should not be understood as limitations on the present disclosure. The positional relationships between the constituent elements are changed as appropriate according to a direction where the constituent elements are described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, it may be a fixed connection, a detachable connection, or an integral connection; it may be a mechanical connection or a connection; it may be a direct connection, an indirect connection through a middleware, or an internal communication inside two elements. Those of ordinary skills in the art may understand meanings of the aforementioned terms in the present disclosure according to situations.

In the specification, “electrical connection” includes connection of composition elements through an element with a certain electrical action. The “element with a certain electrical action” is not particularly limited as long as electrical signals between the connected constituent elements may be transmitted. Examples of the “element with a certain electrical action” not only include an electrode and a wiring, but also include a switching element such as a transistor, a resistor, an inductor, a capacitor, another element with a plurality of functions, etc.

In the specification, a transistor refers to an element which at least includes three terminals, i.e., a gate, a drain, and a source. The transistor has a channel region between the drain (drain electrode terminal, drain region, or drain electrode) and the source (source electrode terminal, source region, or source electrode), and a current can flow through the drain, the channel region, and the source. In the specification, the channel region refers to a region through which a current mainly flows.

In the specification, a first electrode may be a drain and a second electrode may be a source, or, a first electrode may be a source and a second electrode may be a drain. In a case that transistors with opposite polarities are used, or in a case that a direction of a current is changed during operation of a circuit, or the like, functions of the “source” and the “drain” are sometimes interchangeable. Therefore, the “source” and the “drain” are interchangeable in the specification. In addition, the gate may also be referred to as a control electrode.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

In this specification, a circle, oval, triangle, rectangle, trapezoid, pentagon or hexagon, etc. is not strictly speaking, but may be an approximate circle, oval, triangle, rectangle, trapezoid, pentagon or hexagon, etc. Some small deformations due to tolerances may exist, for example, guide angles, curved edges and deformations thereof may exist.

A “light transmittance” in the present disclosure refers to an ability of light to pass through a medium, and is a percentage of luminous flux passing through a transparent or translucent body to its incident luminous flux.

In the present disclosure, “about” and “substantially” refer to that a boundary is not defined strictly and a case within a range of process and measurement errors is allowed. In the present disclosure, “substantially the same” refers to a case where numerical values differ by less than 10%.

In the present disclosure, “A extends along a B direction” means that A may include a main body portion and a secondary portion connected with the main body portion, the main body portion is a line, a line segment, or a strip-shaped body, the main body portion extends along the B direction, and a length of the main body portion extending along the B direction is greater than a length of the secondary portion extending along another direction. “A is extended in in the B direction” in the present disclosure means “the main portion of A is extended in the B direction”.

The present embodiment provides a display substrate including: a first display region. The first display region includes a plurality of display island regions arranged in an array and a light transmitting region located between adjacent display island regions. The display island region includes a plurality of first pixel circuits and a plurality of first light emitting elements disposed on a base substrate. At least one first pixel circuit of the plurality of first pixel circuits is electrically connected with at least one first light emitting element of the plurality of first light emitting elements, and is configured to drive the at least one first light emitting element to emit light. First pixel circuits in adjacent display islands are connected in a first direction by a plurality of first signal lines, and first pixel circuits in adjacent display islands are connected in a second direction by a plurality of second signal lines. The first direction intersects with the second direction. The material of the plurality of second signal lines includes a transparent conductive material, or the material of the plurality of first signal lines and the plurality of second signal lines each includes a metal material.

By centrally arranging a plurality of first pixel circuits and a plurality of first light emitting elements in the display island region, the display substrate provided in this embodiment can reduce quantities of isolated islands and slits, which is conducive to reducing the diffraction effect of the display substrate, is conducive to smooth processing, can reduce a display defect (Mura) in the first display region, and can improve the photographing effect.

In some exemplary embodiments, the material of the plurality of first signal lines may include a metal material, the material of the plurality of second signal lines may include a transparent conductive material, and the plurality of second signal lines may be in a same layer. By setting the material of the plurality of second signal lines to include a transparent conductive material, this example facilitates increasing the spacing between adjacent rows of display island regions, increasing the freedom of arranging the second signal lines, increasing the line width of the second signal lines, mitigating the display defect due to the excessive resistance of the second signal lines, and allowing for the enlargement of the light transmitting region. By setting a material of the plurality of first signal lines to include a metal material, a lateral display defect due to the excessive impedance of the transparent conductive material is reduced, and the process can be simplified to avoid excessive opening processes to reduce the cost.

In some exemplary embodiments, the material of the plurality of first signal lines and the plurality of second signal lines may each includes a metal material. The plurality of second signal lines may be in a same layer, or at least one of the plurality of second signal lines and the rest of the second signal lines may be in different layers. By setting the material of the plurality of first signal lines and the plurality of second signal lines each to include a metal material, the example can reduce lateral or longitudinal display defect cases due to the excessive impedance caused by adopting the transparent conductive material, and can simplify the process to avoid excessive openings to reduce the cost, and in addition, can reduce the space occupied by the lines, which is beneficial to improving the light transmittance.

Solutions of the embodiments will be described below through some examples.

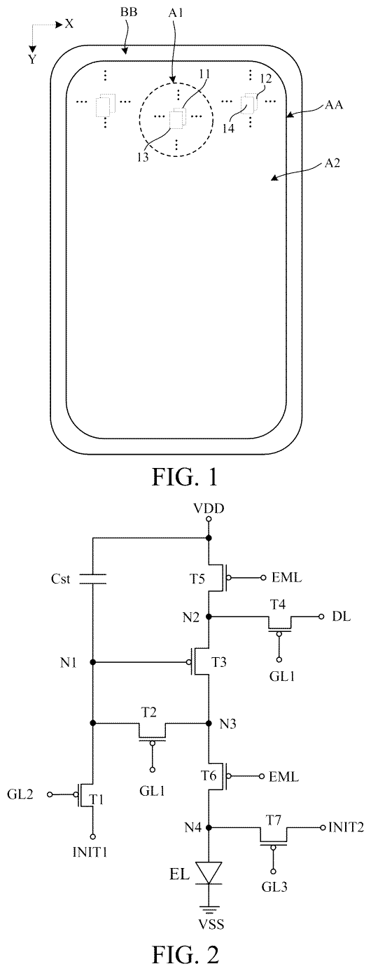

FIG. 1 is a schematic diagram of a display substrate according to at least one embodiment of the present disclosure. In some examples, as shown in FIG. 1, the display substrate may include a display region AA and a peripheral region BB located at a periphery of the display region AA. The display region AA of the display substrate may at least include a first display region A1 and a second display region A2. The second display region A2 may at least partially surround the first display region A1. For Example, the second display region A2 may surround the first display region A1. The peripheral region BB may surround the second display region A2. However, the embodiment is not limited thereto. In other examples, the display region may include only the first display region, and the peripheral region may surround the first display region.

In some examples, as shown in FIG. 1, the first display region A1 may be a light transmitting display region and may also be referred to as a Full Display with Camera (FDC) region. The second display region A2 may be referred to as a normal display region. For example, an orthographic projection of a photosensitive sensor (such as a camera and other hardware) on the display substrate may be within the first display region A1 of the display substrate. In some examples, as shown in FIG. 1, the first display region A1 may be circular and a size of the orthographic projection of the photosensitive sensor on the display substrate may be less than or equal to a size of the first display region A1. However, the embodiment is not limited thereto. In some other examples, the first display region A1 may be rectangular, and a size of the orthographic projection of the photosensitive sensor on the display substrate may be less than or equal to a size of an inscribed circle of the first display region A1.

In some examples, as shown in FIG. 1, the first display region A1 may be located at a middle position of the top of the display area AA. The second display region A2 may locate on the periphery of the first display region A1. However, the embodiment is not limited thereto. For example, the first display region A1 may be located in other positions such as an upper left corner, a lower left corner, a lower right corner or an upper right corner of the display region AA. For example, the second display region A2 may surround at least one side of the first display region A1.

In some examples, as shown in FIG. 1, the display area AA may be in a shape of a rectangle, e.g., a rounded rectangle. The first display region A1 may be circular or elliptical. However, the embodiment is not limited thereto. For example, the first display region A1 may be rectangular, semicircular, pentagonal, or another shape.

In some examples, the display area AA may be provided with a plurality of sub-pixels. At least one sub-pixel may include a pixel circuit and a light emitting element. The pixel circuit may be configured to drive a light emitting element connected thereto. For example, the pixel circuit may be configured to provide a drive current for driving the light emitting element to emit light. The pixel circuit may include a plurality of transistors and at least one capacitor. For example, the pixel circuit may be a circuit having a 3T1C, 4T1C, 5T1C, 5T2C, 6T1C, 7T1C, or 8T1C structure. Among them, in the above circuit structure, T refers to a thin film transistor, C refers to a capacitor, a number before T represents a quantity of thin film transistors in the circuit, and a number before C represents a quantity of capacitors in the circuit.

In some examples, the plurality of transistors in the pixel circuit may be P-type transistors or may be N-type transistors. Use of a same type of transistors in the pixel circuit may simplify a process flow, reduce a process difficulty of the display substrate, and improve a yield of products. In some other examples, the plurality of transistors in the pixel circuit may include a P-type transistor and an N-type transistor.

In some examples, low temperature poly silicon thin film transistors, or oxide thin film transistors, or both of a low temperature poly silicon thin film transistor and an oxide thin film transistor may be used as the plurality of transistors in the pixel circuit. Low Temperature Poly Silicon (LTPS) is used for an active layer of a low temperature poly silicon thin film transistor and an oxide semiconductor (Oxide) is used for an active layer of an oxide thin film transistor. The low temperature poly silicon thin film transistor has advantages such as a high migration rate and fast charging, and the oxide thin film transistor has advantages such as a low leakage current. The low temperature poly silicon thin film transistor and the oxide thin film transistor are integrated on one display substrate, that is, an LTPS+Oxide (LTPO for short) display substrate, advantages of both the low temperature poly silicon thin film transistor and the oxide thin film transistor may be utilized, so that low-frequency drive may be achieved, power consumption may be reduced, and display quality may be improved.

In some examples, the light emitting element may be any of a Light Emitting Diode (LED), an Organic Light Emitting Diode (OLED), a Quantum dot Light Emitting Diode (QLED), a micro LED (including: mini-LED or micro-LED), and the like. For example, the light emitting element may be an OLED, and the light emitting element may emit red light, green light, blue light, or white light, etc. under drive of a pixel circuit corresponding to the light emitting element. A color of light emitted by the light emitting element may be determined as required. In some examples, the light emitting element may include an anode, a cathode, and an organic emitting layer located between the anode and the cathode. The anode of the light emitting element may be electrically connected to a corresponding pixel circuit. However, the embodiment is not limited thereto.

In some examples, one pixel unit of the display region AA may include three sub-pixels. For example, the three sub-pixels may be a red sub-pixel, a green sub-pixel, and a blue sub-pixel, respectively. However, the embodiment is not limited thereto. In some examples, one pixel unit may include four sub-pixels, wherein the four sub-pixels may be a red sub-pixel, a green sub-pixel, a blue sub-pixel, and a white sub-pixel respectively.

In some examples, a shape of the light emitting element may be a rectangle, a rhombus, a pentagon, or a hexagon. When one pixel unit includes three sub-pixels, light emitting elements of the three sub-pixels may be arranged side by side horizontally, side by side vertically, or in a delta-shaped arrangement. When one pixel unit includes four sub-pixels, light emitting elements of the four sub-pixels may be arranged side by side horizontally, side by side vertically, or in a square arrangement. However, the embodiment is not limited thereto.

FIG. 2 is an equivalent circuit diagram of a pixel circuit according to at least one embodiment of the present disclosure. The pixel circuit of this example is described by taking a 7T1C structure as an example.

In some examples, as shown in FIG. 2, the pixel circuit of this example may include seven transistors (i.e. a first transistor T1 to a seventh transistor T7) and one storage capacitor Cst. The light emitting element EL may include an anode, a cathode and an organic emitting layer arranged between the anode and the cathode.

In some examples, as shown in FIG. 2, the display substrate may include a first scan line GL1, a second scan line GL2, a third scan line GL3, a data line DL, a first power supply line VDD, a second power supply line VSS, a light emitting control line EML, a first initial signal line INIT1 and a second initial signal line INIT2.

In some examples, the first power supply line VDD may be configured to provide a constant first voltage signal to the pixel circuit, and the second power supply line VSS may be configured to provide a constant second voltage signal to the pixel circuit, and the first voltage signal may be greater than the second voltage signal. The first scan line GL1 may be configured to provide a first scan signal SCAN1 to the pixel circuit; the data line DL may be configured to provide a data signal to the pixel circuit; the light emitting control line EML may be configured to provide a light emitting control signal EM to the pixel circuit; the second scan line GL2 may be configured to provide a second scan signal SCAN2 to the pixel circuit, and the third scan line GL3 may be configured to provide a third scan signal SCAN3 to the pixel circuit.

In some examples, the second scan line GL2 electrically connected to the nth row of pixel circuits may be electrically connected to the first scan line GL1 electrically connected to the (n−1)th row of pixel circuits, to be input with the first scan signal SCAN1 (n−1), i.e., the second scan signal SCAN2 (n) may be the same as the first scan signal SCAN1 (n−1). The third scan line GL3 of the nth row of pixel circuits may be electrically connected to the first scan line GL1 of the nth row of pixel circuits, to be input with the first scan signal SCAN1 (n), that is, the third scan signal SCAN3 (n) may be the same as the first scan signal SCAN1 (n). Herein, n is an integer greater than 0. Thus, signal lines of the display substrate may be reduced, and a narrow bezel design of the display substrate may be achieved. However, the embodiment is not limited thereto.

In some examples, the first initial signal line INIT1 is configured to provide a first initial signal to the pixel circuit, and the second initial signal line INIT2 is configured to provide a second initial signal to the pixel circuit. For example, the first initial signal may be different from the second initial signal. The first initial signal and the second initial signal may be constant voltage signals, and their magnitudes may be between a first voltage signal and a second voltage signal, but not limited to this. In other examples, the first initial signal and the second initial signal may be the same and only the first initial signal line may be provided to provide the first initial signal.

In some examples, as shown in FIG. 2, a gate of the third transistor T3 is electrically connected with a first node N1, a first electrode of the third transistor T3 is electrically connected with a second node N2, and a second electrode of the third transistor T3 is electrically connected with a third node N3. The third transistor T3 may be referred to as a drive transistor. A gate of the fourth transistor T4 is electrically connected with the first scan line GL1, a first electrode of the fourth transistor T4 is electrically connected with the data line DL, and a second electrode of the fourth transistor T4 is electrically connected with the first electrode of the third transistor T3. The fourth transistor T4 may be referred to as a data writing transistor. A gate of the second transistor T2 is electrically connected with the first scan line GL1, a first electrode of the second transistor T2 is electrically connected with a gate of the third transistor T3, and a second electrode of the second transistor T2 is electrically connected with a second electrode of the third transistor T3. The second transistor T2 may also be referred to as a threshold compensation transistor. A gate electrode of the fifth transistor T5 is electrically connected with the light emitting control line EML, a first electrode of the fifth transistor T5 is electrically connected with the first power supply line VDD, and a second electrode of the fifth transistor T5 is electrically connected with the first electrode of the third transistor T3. A gate of the sixth transistor T6 is electrically connected with the light emitting control line EML, a first electrode of the sixth transistor T6 is electrically connected with the second electrode of the third transistor T3, and a second electrode of the sixth transistor T6 is electrically connected with an anode of the light emitting element EL. The fifth transistor T5 and the sixth transistor T6 may be referred to as light emitting control transistors. The first transistor T1 is electrically connected with the gate of the third transistor T3 and configured to reset the gate of the third transistor T3, and the seventh transistor T7 is electrically connected with the anode of the light emitting element EL and configured to reset the anode of the light emitting element EL. A gate of the first transistor T1 is electrically connected with a second scan line GL2, a first electrode of the first transistor T1 is electrically connected with a first initial signal line INIT1, and a second electrode of the first transistor T1 is electrically connected with the gate of the third transistor T3. A gate of the seventh transistor T7 is connected with the third scan line GL3, a first electrode of the seventh transistor T7 is connected with the second initial signal line INIT2, and a second electrode of the seventh transistor T7 is connected with the anode of the light emitting element EL. The first transistor T1 and the seventh transistor T7 may also be referred to as reset control transistors. A first electrode plate of the storage capacitor Cst is electrically connected with the gate electrode of the third transistor T3, and a second electrode plate of the storage capacitor Cst is electrically connected with the first power supply line VDD.

In this example, the first node N1 is a connection point for the storage capacitor Cst, the first transistor T1, the third transistor T3 and the second transistor T2, the second node N2 is a connection point for the fifth transistor T5, the fourth transistor T4, and the third transistor T3, the third node N3 is a connection point for the third transistor T3, the second transistor T2, and the sixth transistor T6, the fourth node N4 is a connection point for the sixth transistor T6, the seventh transistor T7, and the light emitting element EL.

A working process of the pixel circuit is explained below. The description is given by taking a case in which a plurality of transistors included in the pixel circuit shown in FIG. 2 are all P-type transistors as an example. In this example, the third scan signal provided by the third scan line GL3 may be the same as the first scan signal provided by the first scan line GL1.

In some examples, the working process of the pixel circuit may include a first stage, a second stage and a third stage during a one-frame display period.

The first stage is referred to as a reset stage. The second scan signal SCAN2 provided by the second scan line GL2 may be a low-level signal, so that the first transistor T1 is turned on, and a first initial signal provided by the first initial signal line INIT1 is provided to the first node N1 to initialize the first node N1 and clear an original data voltage in the storage capacitor Cst. The first scan signal SCAN1 provided by the first scan line GL1 may be a high-level signal, and the light emitting control signal EM provided by the light emitting control line EML may be a high-level signal, so that the fourth transistor T4, the second transistor T2, the fifth transistor T5, the sixth transistor T6, and the seventh transistor T7 are turned off. In this stage, the light emitting element EL does not emit light.

The second stage is referred to as a data writing stage or a threshold compensation stage. The first scan signal SCAN1 provided by the first scan line GL1 may be a low-level signal, the second scan signal SCAN2 provided by the second scan line GL2 and the light emitting control signal EM provided by the light emitting control line EML may both be high-level signals, and the data line DL outputs a data signal DATA. In this stage, since the first electrode plate of the storage capacitor Cst is at a low level, the third transistor T3 is turned on. The first scan signal line SCAN1 is the low-level signal, so that the second transistor T2, the fourth transistor T4, and the seventh transistor T7 are turned on. The second transistor T2 and the fourth transistor T4 are turned on, so that a data voltage Vdata output by the data line DL is provided to the first node N1 through the second node N2, the turned-on third transistor T3, the third node N3, and the turned-on second transistor T2, and the storage capacitor Cst is charged with a difference between the data voltage Vdata output by the data line DL and a threshold voltage of the third transistor T3. A voltage of the first electrode plate (i.e., the first node N1) of the storage capacitor Cst is Vdata−|Vth|, wherein Vdata is the data voltage output by the data line DL, and Vth is the threshold voltage of the third transistor T3. The seventh transistor T7 is turned on, so that a second initial signal provided by the second initial signal line INIT2 is provided to the anode of the light emitting element EL to initialize (reset) the anode of the light emitting element EL and clear a pre-stored voltage therein, so as to complete initialization, thereby ensuring that the light emitting element EL does not emit light. The second scan signal SCAN2 provided by the second scan line GL2 may be a high-level signal so that the first transistor T1 is turned off. The light emitting control signal EM provided by the light emitting control signal line EML is a high-level signal, so that the fifth transistor T5 and the sixth transistor T6 are turned off.

The third stage is referred to as a light emitting stage. The light emitting control signal EM provided by the light emitting control line EML is a low-level signal, and the first scan signal SCAN1 provided by the first scan line GL1 and the second scan signal SCAN2 provided by the second scan line GL2 are high-level signals. The light emitting control signal EM provided by the light emitting control line EML is a low-level signal, so that the fifth transistor T5 and the sixth transistor T6 are turned on, and the first voltage signal output from the first power supply line VDD provides drive voltage to the anode of the light emitting device EL through the turned-on fifth transistor T5, the third transistor T3 and the sixth transistor T6 to drive the light emitting element EL to emit light.

In a drive process of the pixel circuit, a drive current flowing through the third transistor T3 is determined by a voltage difference between the gate and the first electrode of the third transistor T3. Since the voltage of the first node N1 is Vdata−|Vth|, the drive current of the third transistor T3 is as follows.

I=K×(Vgs−Vth)²=K×[(Vdd−Vdata+|Vth|)−Vth]²=K×[Vdd−Vdata]²

Herein, I is the drive current flowing through the third transistor T3, that is, a drive current for driving the light emitting element EL, K is a constant, Vgs is the voltage difference between the gate electrode and the first electrode of the third transistor T3, Vth is the threshold voltage of the third transistor T3, Vdata is the data voltage outputted by the data line DL, and Vdd is the first voltage signal outputted by the first power supply line VDD.

It may be seen from the above formula that a current flowing through the light emitting element EL is independent of the threshold voltage of the third transistor T3. Therefore, the pixel circuit according to this embodiment may better compensate the threshold voltage of the third transistor T3.

In some examples, as shown in FIG. 1, the first display region Al may include a plurality of first pixel circuits 11 and a plurality of first light emitting elements 13, at least one of the plurality of first pixel circuits 11 and at least one of the plurality of first light emitting elements 13 are electrically connected, and the at least one pixel circuit 11 may be configured to drive the connected at least one first light emitting element 13 to emit light. Orthographic projections of the first light emitting element 13 and the connected first pixel circuit 11 on the base substrate may at least partially overlap. For example, the plurality of first pixel circuits 11 and the plurality of first light emitting elements 13 may be electrically connected in one-to-one correspondence.

In some examples, as shown in FIG. 1, the second display region A2 may include a plurality of second pixel circuits 12 and a plurality of second light emitting elements 14. At least one of the plurality of second pixel circuits 12 and at least one of the plurality of second light emitting elements 14 are electrically connected, and the at least one second pixel circuit 12 may be configured to drive the connected at least one second light emitting element 14 to emit light. Orthographic projections of the second light emitting element 14 and the connected second pixel circuit 12 on the base substrate may at least partially overlap. For example, the plurality of second pixel circuits 12 and the plurality of second light emitting elements 14 may be electrically connected in one-to-one correspondence.

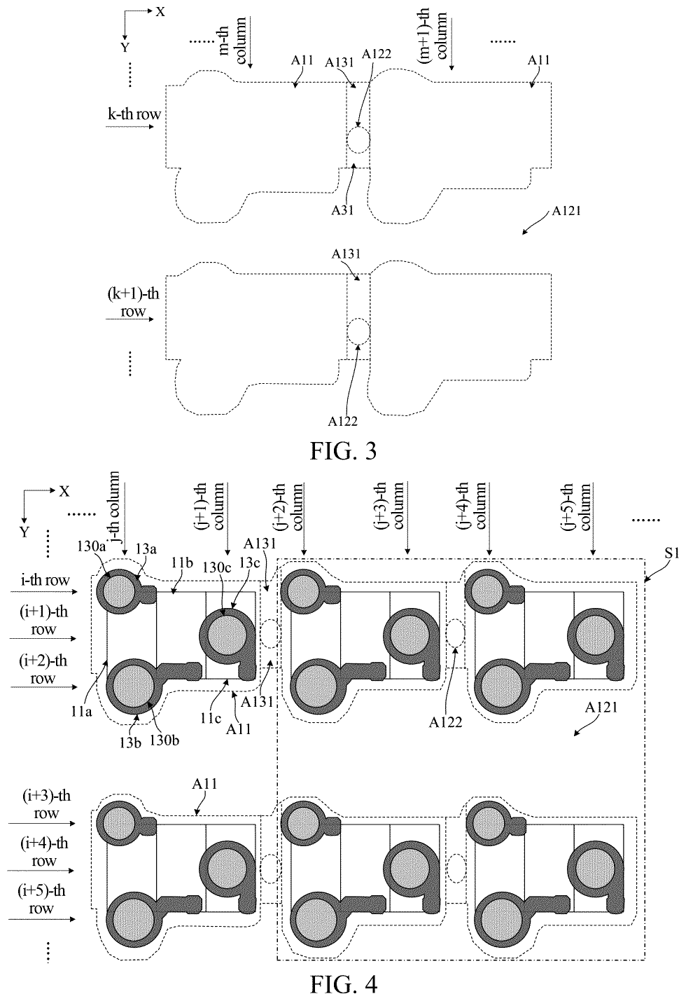

FIG. 3 is a partial schematic diagram of a first display region according to at least one embodiment of the present disclosure. In some examples, as shown in FIG. 3, in a plane parallel to the display substrate, the first display region A1 may include a plurality of display island regions A11 arranged in an array. Each display island region A11 may be configured to perform image display. The plurality of display island regions A11 may be arranged in an array in a first direction X and a second direction Y. The first direction X and the second direction Y may intersect, for example, the first direction X may be perpendicular to the second direction Y. A plurality of display island regions A11 arranged in the first direction X may be referred to as a row of display island regions, and a plurality of display island regions arranged in the second direction Y may be referred to as a column of display island regions.

In some examples, as shown in FIG. 3, the shapes of the plurality of display island regions A11 may be substantially the same in a plane parallel to the display substrate. For example, the display island region A11 may have an irregular shape to provide sufficient light emitting region to ensure a display effect. The display island region A11 may have smooth edges thereby reducing the light diffraction effect to help improve the photographing effect.

In some examples, as shown in FIG. 3, a light transmitting region is provided between adjacent display island regions A11. Each light transmitting region may be configured to provide a light transmissive space. For example, the light transmitting region may include a first light transmitting region A121 and a second light transmitting region A122. The first light transmitting region A121 may be located between two adjacent row of display island regions (e.g. the k-th row of display island regions and the (k+1)-th row of display island regions, where k is an integer greater than 0). A plurality of first light transmitting regions A121 and a plurality of rows of display island regions A11 may be provided at intervals. A plurality of second light transmitting regions A122 may be located between two adjacent columns of display island regions A11 (e.g. the m-th column of display island regions and the (m+1)-th column of display island regions, where m is an integer greater than 0). For example, the plurality of second light transmitting regions A122 may be independently provided. The plurality of second light transmitting regions A122 may be arranged sequentially in the second direction Y, and the second light transmitting regions A122 may not be communicated with the first light transmitting regions A121. A second light transmitting region A122 may be located between two adjacent display island regions A11 in one row of display island regions A11. For example, the area of a single first light transmitting region A121 may be larger than the area of a single second light transmitting region A122. However, the embodiment is not limited thereto. For example, a second light transmitting region A122 may communicate with a first light transmitting region A121 adjacent in the second direction Y.

In some examples, as shown in FIG. 3, a plurality of first line regions A131 may be provided between the display island regions A11. The plurality of first line regions A131 may be independently provided. A first line region A131 may be located between two adjacent display island regions A11 in one row of display island regions A11. Adjacent display island regions A11 in one row of display island regions A11 may be communicated through the first line region A131. The second light transmitting region A122 may be surrounded by the first line region A131; alternatively, the second light transmitting region A122 may be surrounded by the first line region A131 and the display island region A11. The present example implements signal transmission in the first direction X between the display island regions A11 by providing the first line region A131.

FIG. 4 is a schematic diagram of an arrangement between a first pixel circuit and the first light emitting element in the first display region according to at least one embodiment of the present disclosure. In some examples, as shown in FIG. 4, one display island region A11 may include one first pixel unit, and the one first pixel unit may include three first sub-pixels, each of which may include a first pixel circuit and a first light emitting element. The three first sub-pixels within the display island region A11 may be configured to emit light of different colors.

In some examples, as shown in FIG. 4, the display island region A11 may include three first pixel circuits (e.g. including first pixel circuits 11a, 11b, and 11c) and three first light emitting elements (e.g. including first light emitting elements 13a, 13b, and 13c). The three first pixel circuits and the three first light emitting elements can be electrically connected in one-to-one correspondence. The first pixel circuit 11a may be electrically connected to the first light emitting element 13a, the first pixel circuit 11b may be electrically connected to the first light emitting element 13b, and the first pixel circuit 11c may be electrically connected to the first light emitting element 13c.

In some examples, the first light emitting element 13a may be configured to emit light of a first color, the first light emitting element 13b may be configured to emit light of a second color, and the first light emitting element 13c may be configured to emit light of a third color. In some examples, the light in the first color may be red light, the light in the second color may be green light, and the light in the third color may be blue light. That is, the first light emitting element 13a may be a red light emitting element, the first light emitting element 13b may be a green light emitting element and the first light emitting element 13c may be a blue light emitting element.

In some examples, as shown in FIG. 4, the first pixel circuits 11a, 11b and 11c within one display island region A11 may be arranged sequentially along the first direction X. A plurality of first pixel circuits in one row of display island regions A11 may be arranged in one row along the first direction X, and a plurality of first pixel circuits in one column of display island regions A11 may be arranged in three columns along the second direction Y.

In some examples, as shown in FIG. 4, the first light emitting elements 13a and 13b in one display island region A11 may be arranged sequentially along the second direction Y, and the first light emitting element 13c may be located at a same side of the first light emitting elements 13a and 13b in the first direction X. In a row of display island regions A11, a plurality of first light emitting elements 13a may be arranged in the i-th row, a plurality of first light emitting elements 13c may be arranged in the (i+1)-th row, a plurality of first light emitting elements 13b may be arranged in the (i+2)-th row, and a plurality of rows of first light emitting elements may be arranged repeatedly according to the above rule. The first light emitting elements 13a and the first light emitting elements 13b in the display island regions A11 may be alternately arranged in the second direction Y. In a column of display island regions A11, a plurality of first light emitting elements 13a and a plurality of first light emitting elements 13b may be alternately arranged in the j-th column, a plurality of first light emitting elements 13c may be sequentially arranged in the (j+1)-th column, and a plurality of columns of first light emitting elements may be repeatedly arranged according to the above rule. Here, i and j are integers greater than 0. In this example, three rows of first light emitting elements may be arranged in one row of display island regions A11, and two columns of first light emitting elements may be arranged in one column of display island regions A11.

In some examples, as shown in FIG. 4, the first light emitting element 13a may have a light emitting region 130a, the first light emitting element 13b may have a light emitting region 130b and the first light emitting element 13c may have a light emitting region 130c. The light emitting region 130a of the first light emitting element 13a, the light emitting region 130b of the first light emitting element 13b and the light emitting region 130c of the first light emitting element 13c may all be substantially circular or elliptical. The area of the light emitting region 130a of the first light emitting element 13a may be smaller than the area of the light emitting region 130b of the first light emitting element 13b and may be smaller than the area of the light emitting region 130c of the first light emitting element 13c. The area of the light emitting region 130b of the first light emitting element 13b and the area of the light emitting region 130c of the first light emitting element 13c may be substantially the same. A light emitting region of the light emitting element of the present example refers to a portion of the light emitting element located in a pixel opening of a pixel definition layer.

In some examples, as shown in FIG. 4, an orthographic projection of the light emitting region 130a of the first light emitting element 13a on the base substrate and an orthographic projection of the first pixel circuit 11a on the base substrate may partially overlap. An orthographic projection of the light emitting region 130b of the first light emitting element 13b on the base substrate may not overlap an orthographic projection of the connected first pixel circuit 11b on the base substrate, and an orthographic projection of the light emitting region 130b on the base substrate may partially overlap an orthographic projection of the first pixel circuit 11a on the base substrate. An orthographic projection of the light emitting region 130c of the first light emitting element 13c on the base substrate and an orthographic projection of the connected first pixel circuit 11c on the base substrate may at least partially overlap, for example, the orthographic projection of the light emitting region 130c on the base substrate may be within a range of the orthographic projection of the first pixel circuit 11c on the base substrate.

The arrangement of the three first pixel circuits and the three first light emitting elements of the display substrate of the present example is favorable for centralized provision. By providing the three first pixel circuits and the three first light emitting elements as one first pixel unit in a display island region, the arrangement of the display island regions in an array is facilitated, the space between the display island regions can be increased, to avoid the high quantity of display isolated islands and recessed slits caused by the provision of one first pixel circuit and one first light emitting element separately in each display island region. The light diffraction of the first display region can be improved by reducing quantities of isolated islands and slits, and the edge of the display island region can be conveniently smoothed.

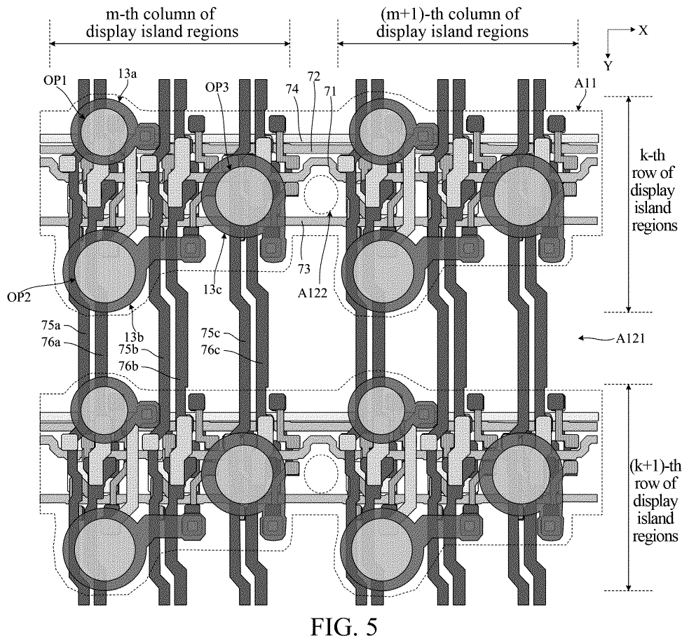

FIG. 5 is a schematic partial top view of region S1 in FIG. 4. Four display island regions A11 arranged in a 2×2 array are illustrated in FIG. 5.

In some examples, in a direction perpendicular to the display substrate, the display substrate may include a base substrate, a circuit structure layer and a light emitting structure layer sequentially disposed on the base substrate. The circuit structure layer of the first display region may include at least a plurality of first pixel circuits, and the light emitting structure layer may include at least a plurality of first light emitting elements. A first light emitting element may include at least an anode, an organic light emitting layer, and a cathode, and the anode of the first light emitting element may be connected to a corresponding first pixel circuit.

In some examples, in a direction perpendicular to the display substrate, the circuit structure layer of the first display region may include a semiconductor layer, a first conductive layer, a second conductive layer, a third conductive layer, a transparent conductive layer, and a fourth conductive layer that are sequentially disposed on the base substrate. A first insulating layer may be provided between the semiconductor layer and the first conductive layer, a second insulating layer may be provided between the first conductive layer and the second conductive layer, a third insulating layer may be provided between the second conductive layer and the third conductive layer, a fourth insulating layer may be provided between the third conductive layer and the transparent conductive layer, a fifth insulating layer may be provided between the transparent conductive layer and the fourth conductive layer, and a sixth insulating layer may be provided on a side of the fourth conductive layer away from the base substrate.

In some examples, the light emitting structure layer may include at least an anode layer, a pixel definition layer, an organic light emitting layer, and a cathode layer that are sequentially disposed on the base substrate. The anode layer may be electrically connected with the first pixel circuit of the circuit structure layer, the organic light emitting layer may be connected with the anode layer, the cathode layer may be connected with the organic light emitting layer, and the organic light emitting layer emits light of corresponding colors under drive of the anode layer and the cathode layer. An encapsulation structure layer may be provided on a side of the light emitting structure layer away from the base substrate. The encapsulation structure layer may include a first encapsulation layer, a second encapsulation layer, and a third encapsulation layer that are stacked. The first encapsulation layer and the third encapsulation layer may be made of an inorganic material, the second encapsulation layer may be made of an organic material, and the second encapsulation layer may be arranged between the first encapsulation layer and the third encapsulation layer to form a laminated structure of inorganic material/organic material/inorganic material, which may ensure that external moisture cannot enter the light emitting structure layer. In some possible implementations, the display substrate may further include another film layers, such as a touch structure layer, a color filter layer, or the like, which is not limited here in the present disclosure.

Exemplary description is made below for a structure and a manufacturing process of a display substrate according to the present example. A “patterning process” mentioned in the present disclosure includes photoresist coating, mask exposure, development, etching, photoresist stripping, etc., for a metal material, an inorganic material, or a transparent conductive material, and includes organic material coating, mask exposure, development, etc., for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a certain material on a base substrate using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process.

“A and B are arranged in the same layer” or “A and B are of a structure of a same layer” in the present disclosure refers to that A and B are simultaneously formed by a same patterning process. “A and B are of structures of different layers” means that A and B are respectively formed by at least two patterning processes. A “thickness” of a film layer is a dimension of the film layer in a direction perpendicular to the display substrate. In an exemplary implementation of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A is overlapped with the boundary of the orthographic projection of B. “The shape of A” in the present disclosure refers to the shape of an orthographic projection of A on the base substrate.

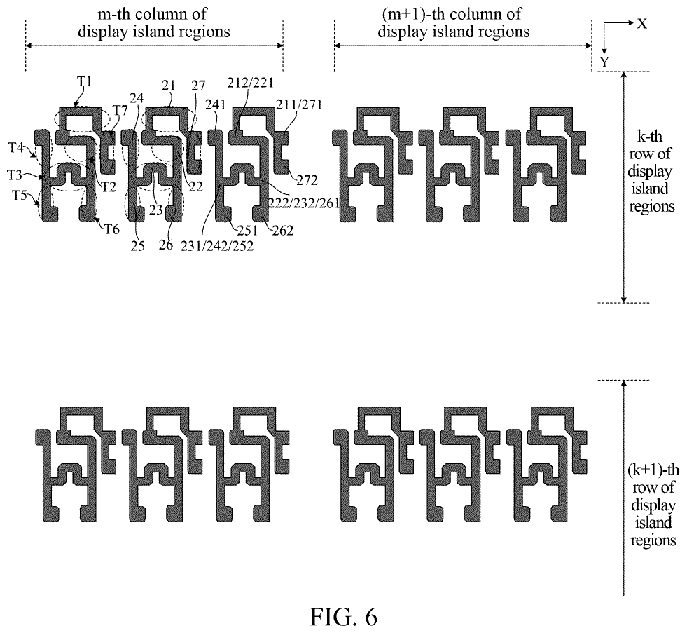

In some examples, the preparing process for the display substrate according to the present example may include the following operations. The structure of the region where each first pixel circuit is located in the circuit structure layer of the display substrate is approximately the same and description is given below by taking the structure of the region where a first first pixel circuit is located as an example.
(1-1) The base substrate is provided. In some examples, the base may be a rigid base or a flexible base. For example, the rigid base substrate may be made of, but not limited to, one or more of glass and quartz. The flexible base substrate may be made of, but not limited to, one or more of polyethylene terephthalate, ethylene terephthalate, polyether ether ketone, polystyrene, polycarbonate, polyarylate, polyarylester, polyimide, polyvinyl chloride, polyethylene, and textile fibers. In some examples, the flexible base may include a first flexible material layer, a first inorganic material layer, a second flexible material layer and a second inorganic material layer which are stacked. The first flexible material layer and the second flexible material layer may be made of a material such as polyimide (PI), polyethylene terephthalate (PET), or a polymer soft film on which surface treatment is performed, and materials of the first inorganic material layer and the second inorganic material layer may be silicon nitride (SiNy,y>0) or silicon oxide (SiOx,x>0), etc., which are used to improve resistance to water and oxygen of the base substrate.
(1-2) The semiconductor layer is formed. In some examples, a semiconductor thin film is deposited on the base substrate and patterned through a patterning process to form a semiconductor layer disposed on the base substrate, as shown in FIG. 6. FIG. 6 is a schematic diagram of the display substrate after a semiconductor layer is formed in FIG. 5.

In some examples, as shown in FIG. 6, the semiconductor layer of a single display island region in the display substrate may include at least first active layers 21 of first transistors T1, second active layers 22 of second transistors T2, third active layers 23 of third transistors T3, fourth active layers 24 of fourth transistors T4, fifth active layers 25 of fifth transistors T5, sixth active layers 26 of sixth transistors T6, and seventh active layers 27 of seventh transistors T7 of the three first pixel circuits.

In some examples, the first active layer 21, the second active layer 22, the third active layer 23, the fourth active layer 24, the fifth active layer 25, the sixth active layer 26, and the seventh active layer 27 of each first pixel circuit may be of an interconnected integral structure. The fifth active layer 25 and the sixth active layer 26 may be located on one side of the third active layer 23 in the second direction Y, and the fourth active layer 24, the second active layer 22, the first active layer 21 and the seventh active layer 27 may be located on the other side of the third active layer 23 in the second direction Y. The first active layer 21 may be located on a side of the second active layer 22 away from the third active layer 23 in the second direction Y. The seventh active layer 27 may be located on a side of the second active layer 22 away from the fourth active layer 24 in the first direction X. Active layers of transistors of adjacent first pixel circuits in a display island region can be independently provided.

In some examples, the first active layer 21 may be generally U-shaped, the second active layer 22 may be generally L-shaped, the third active layer 23 may be generally n-shaped, and the fourth active layer 24, the fifth active layer 25, the sixth active layer 26, and the seventh active layer 27 may be generally I-shaped.

In some examples, an active layer of each transistor may include: a first region, a second region, and a channel region located between the first region and the second region. In some examples, the first region 211 of the first active layer 21 is connected to the first region 271 of the seventh active layer 27, and the first region 211 of the first active layer 21 may simultaneously serve as the first region 271 of the seventh active layer 27. The second region 212 of the first active layer 21 is connected to the first region 221 of the second active layer 22, and the second region 212 of the first active layer 21 may simultaneously serve as the first region 221 of the second active layer 22. The first region 231 of the third active layer 23 may be connected with the second region 242 of the fourth active layer 24 and the second region 252 of the fifth active layer 25, and the first region 231 of the third active layer 23 may simultaneously serve as the second region 242 of the fourth active layer 24 and the second region 252 of the fifth active layer 25, forming a second node of the first pixel circuit. The second region 232 of the third active layer 23 may be connected with the second region 222 of the second active layer 22 and the first region 261 of the sixth active layer 26, and the second region 232 of the third active layer 23 may simultaneously serve as the second region 222 of the second active layer 22 and the first region 261 of the sixth active layer 26, forming a third node of the first pixel circuit. The first region 241 of the fourth active layer 24, the first region 251 of the fifth active layer 25, the second region 252 of the sixth active layer 26, and the second region 272 of the seventh active layer 27 may be provided separately. The first region 241 of the fourth active layer 24 may be located on a side of the second region 212 of the first active layer 21 away from the first region 211 of the first active layer 21 in the first direction X. The first region 251 of the fifth active layer 25 may be located on a side of the third active layer 23 away from the first region 241 of the fourth active layer 24 in the second direction Y. The second region 262 of the sixth active layer 26 may be adjacent to the first region 251 of the fifth active layer 25 in the first direction X. The second region 272 of the seventh active layer 27 may be adjacent to the second region 222 of the second active layer 22 in the first direction X.

In some examples, semiconductor layers in adjacent display island regions may be spaced from each other. For example, active layers of a plurality of transistors of first pixel circuits in adjacent display island regions in the first direction X may not be connected, and active layers of a plurality of transistors of first pixel circuits in adjacent display island regions in the second direction Y may not be connected.
(1-3) The first conductive layer is formed. In some examples, a first insulating thin film and a first conductive thin film are sequentially deposited on the base substrate on which the above-mentioned patterns are formed, and the first conductive thin film is patterned through a patterning process to form a first insulating layer disposed on the semiconductor layer and a first conductive layer disposed on the first insulating layer. In some examples, the first conductive layer may also be referred to as a first gate metal layer. The first insulating layer may also be referred to as a first gate insulating layer.

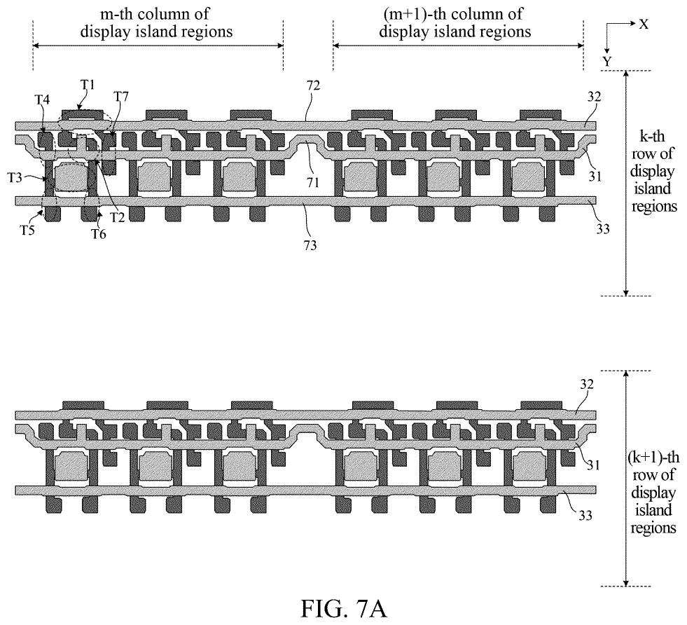

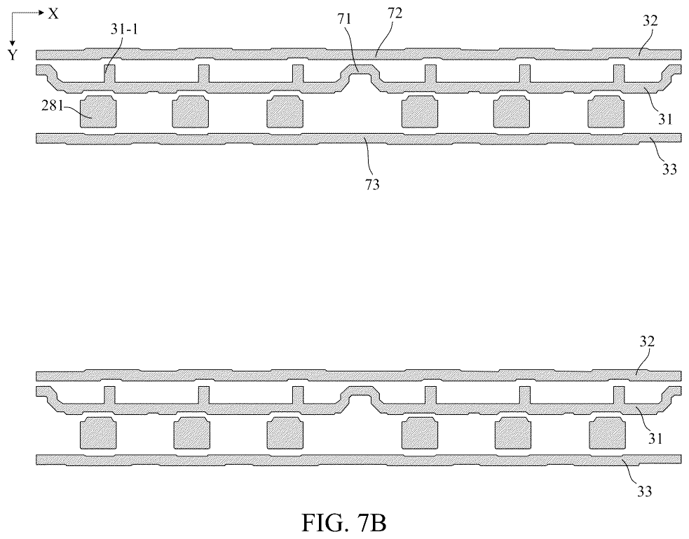

FIG. 7A is a schematic diagram of the display substrate after a first conductive layer is formed in FIG. 5. FIG. 7B is a schematic diagram of a first conductive layer in FIG. 7A. In some examples, as shown in FIGS. 7A and 7B, the first conductive layer of a single display island region of the first display region may include at least a first scan line 31, a second scan line 32, a light emitting control line 33, and first electrode plates 281 of storage capacitors of the three first pixel circuits.

In some examples, the first scan line 31, the second scan line 32, and the light emitting control line 33 may all be in a shape of a line in which a main body portion extends in the first direction X, for example, may be in a shape of a straight line which extends in the first direction X. The second scan line 32, the first scan line 31, and the light emitting control line 33 in the display island region may be arranged sequentially in the second direction Y. The first scan line 31 may be located at a side of the second scan line 32 in the second direction Y and the light emitting control line 33 may be located at a side of the first scan line 31 in the second direction Y. The first scan line 31 may be located between the second scan line 32 and the light emitting control line 33. The first electrode plate 281 of the storage capacitor of the first pixel circuit may be located between the first scan line 31 and the light emitting control line 33. The first electrode plates 281 of the storage capacitors of the three first pixel circuits may be sequentially disposed in the first direction X.

In some examples, an orthographic projection of the first electrode plate 281 of the storage capacitor on the base substrate may be generally rectangular, for example, may be rounded rectangular. The orthographic projection of the first electrode plate 281 of the storage capacitor on the base substrate and an orthographic projection of the third active layer 13 of the third transistor T3 on the base substrate may at least partially overlap, and the first electrode plate 281 may simultaneously serve as a lower electrode plate of the storage capacitor and a gate of the third transistor T3.

In some examples, orthographic projections of the second scan line 32 and the first active layer 21 of the first transistor T1 on the base substrate may partially overlap. A region where the second scan line 32 is overlapped with the first active layer 21 may serve as a gate electrode of the first transistor T1 with a double-gate structure.

In some examples, a region where the first scan line 31 overlaps the fourth active layer 24 of the fourth transistor T4 may serve as a gate of the fourth transistor T4. A region where the first scan line 31 overlaps the seventh active layer 27 of the seventh transistor T7 may serve as a gate of the seventh transistor T7. A region where the first scan line 31 overlaps the second active layer 22 of the second transistor T2 may serve as a first gate of the second transistor T2.

In some examples, a side of the first scan line 31 close to the second scan line 32 may be provided with a scan extension segment 31-1. The scan extension segment 31-1 may be provided in each pixel circuit. A first end of the scan extension segment 31-1 is connected to the first scan line 31, and a second end of the scan extension segment 31-1 extends in a direction of the second scan line 32. A region where the scan extension segment 31-1 overlaps the second active layer 22 may serve as a second gate of the second transistor T2 to realize a second transistor T2 with a double-gate structure. The plurality of scan extensions 31-1 and the first scan line 31 may be of an interconnected integral structure.

In some examples, a region where the light emitting control line 33 overlaps the fifth active layer 25 of the fifth transistor T5 may serve as a gate of the fifth transistor T5. A region where the light emitting control line 33 overlaps the sixth active layer 26 of the sixth transistor T6 may serve as a gate of the sixth transistor T6.

In some examples, the first conductive layer of the first line region between display island regions adjacent in the first direction X may include at least a first scan connection line 71, a second scan connection line 72, and a light emitting control connection line 73. The first scan connection line 71, the second scan connection line 72, and the light emitting control connection line 73 may all be in a shape of a line in which a main portion extends in the first direction X, for example, the second scan connection line 72 and the light emitting control connection line 73 may be in a shape of a straight line which extends in the first direction X, and the first scan connection line 71 may be in a shape of a bending line or curved line extending in the first direction X. The first scan connection line 71 may be bent to a side of the second scan connection line 72. The first scan connection line 71 may be located at a side of the second scan connection line 72 in the second direction Y and the light emitting control connection line 73 may be located at a side of the first scan connection line 71 in the second direction Y. The first scan connection line 71 may be located between the second scan connection line 72 and the light emitting control connection line 73.

In some examples, the boundary of the second light transmitting region in the second direction Y may be limited by the first scan connection line 71 and the light emitting control connection line 73. By adopting a design in which the first scan connection line 71 is bent to a side of the second scan connection line 72, the present example facilitates increasing the area of the second light transmitting region. In other examples, the second scan connection line 72 may be designed to be bent away from the first scan connection line 71, and the light emitting control connection line 73 may be designed to be bent away from the first scan connection line 71 to increase the area of the second light transmitting region. In other examples, the light emitting control connection line 73 may be designed to be bent close to the first scan connection line 71 so that the first light transmitting region and the second light transmitting region can be communicated to improve the diffraction caused by the isolated slots.

In some examples, first scan lines 31 in display island regions adjacent along the first direction X may be connected by a first scan connection line 71. Two ends of the first scan connection lines 71 may be connected to first scan lines 31 in two adjacent display island regions respectively. Second scan lines 32 in display island regions adjacent in the first direction X may be connected by a second scan connection line 72. Two ends of the second scan connection line 72 may be connected to second scan lines 32 in two adjacent display island regions respectively. Light emitting control lines 33 in the display island regions adjacent in the first direction X may be connected by a light emitting control connection line 73. Two ends of the light emitting control connection line 73 may be connected to light emitting control lines 33 in two adjacent display island regions respectively.

In some examples, after the pattern of the first conductive layer is formed, the semiconductor layer may be subjected to a conductive treatment by using the first conductive layer as a shield. A region of the semiconductor layer, which is shielded by the first conductive layer, forms channel regions of the first transistor T1 to the seventh transistor T7, and a region of the semiconductor layer, which is not shielded by the first conductive layer, may be made to be conductive, that is, first regions and second regions of the first active layer 21 to the seventh active layer 27 may be all made to be conductive.
(1-4) The second conductive layer is formed. In some examples, a second insulating thin film and a second conductive thin film are sequentially deposited on the base substrate on which the above-mentioned patterns are formed, and the second conductive thin film is patterned through a patterning process to form a second insulating layer disposed on the first conductive layer and a second conductive layer disposed on the second insulating layer. In some examples, the second conductive layer may also be referred to as a second gate metal layer. The second insulating layer may also be referred to as a second gate insulating layer.

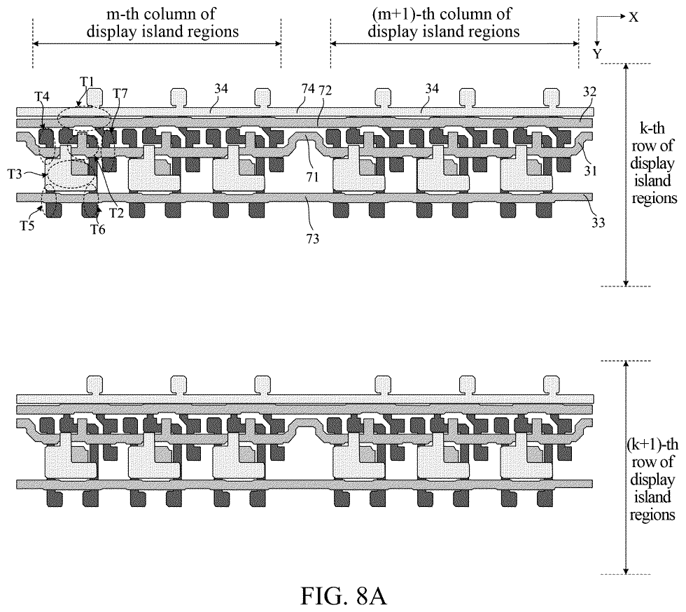

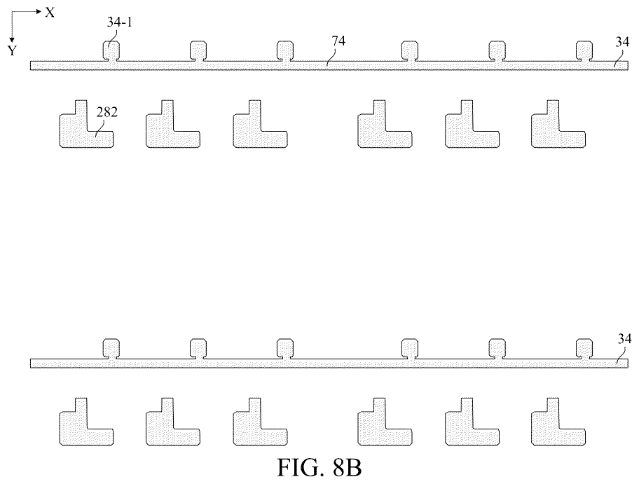

FIG. 8A is a schematic diagram of the display substrate after a second conductive layer is formed in FIG. 5. FIG. 8B is a schematic diagram of a second conductive layer in FIG. 8A. In some examples, as shown in FIGS. 8A and 8B, the second conductive layer of a single display island region of the first display region may include at least a first initial signal line 34, and second electrode plates 282 of the storage capacitors of the three first pixel circuits.

In some examples, the first initial signal line 34 may be in a shape of a straight line in which a main portion extends in the first direction X. An orthographic projection of the first initial signal line 34 on the base substrate may be located at a side of an orthographic projection of the second scan line 32 on the base substrate away from an orthographic projection of the first scan line 31 on the base substrate. An orthographic projection of the first initial signal line 34 on the base substrate and an orthographic projection of the second scan line 32 on the base substrate may partially overlap or may not overlap.

In some examples, the second electrode plate 282 of the storage capacitor of the first pixel circuit may be located at a side of the first initial signal line 34 in the second direction Y. An orthographic projection of the second electrode plate 282 of the storage capacitor on the base substrate and an orthographic projection of the first electrode plate 281 on the base substrate may partially overlap. For example, the orthographic projection of the second electrode plate 282 on the base substrate may be substantially L-shaped. The second electrode plates 282 of the storage capacitors of three first pixel circuits may be sequentially disposed in the first direction X.

In some examples, a side of the first initial signal line 34 away from the second electrode plate 282 may be provided with an initial connection block 34-1, which may be provided in each pixel circuit of the display island region. A first end of the initial connection block 34-1 is connected to the first initial signal line 34 and a second end of the initial connection block 34-1 extends in a direction away from the second electrode plate 282. The initial connection block 34-1 may be configured to be electrically connected to the first connection electrode 41 through a ninth via V9 formed subsequently. In some examples, the first initial signal line 34 and the plurality of initial connection blocks 34-1 may be of an interconnected integral structure.

In some examples, the second conductive layer of the first line region between display island regions adjacent in the first direction X may include at least a first initial connection line 74. The first initial connection line 74 may be in a shape of a straight line in which a main portion extends in the first direction X. An orthographic projection of the first initial connection line 74 on the base substrate may be located at a side of an orthographic projection of the second scan connection line 72 on the base substrate away from an orthographic projection of the first scan connection line 71 on the base substrate.

In some examples, first initial signal lines 34 in display island regions adjacent along the first direction X may be connected by a first initial connection line 74. Two ends of the first initial connection line 74 may be respectively connected to first initial signal lines 34 in adjacent display island regions.
(1-5) A third insulation layer is formed. In some examples, a third insulation thin film is deposited on the base substrate on which the aforementioned patterns are formed, and the third insulation thin film is patterned through a patterning process to form a third insulation layer. The third insulating layer may be provided with a plurality of vias. The third insulating layer may also be referred to as an interlayer insulating layer.

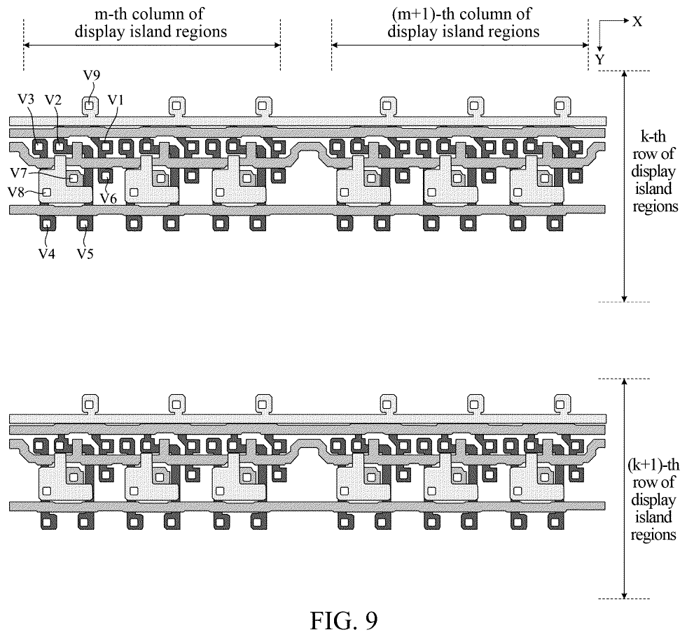

FIG. 9 is a schematic diagram of the display substrate after a third insulation layer is formed in FIG. 5. In some examples, the plurality of vias of the third insulating layer of a single display island region may include at least a first via V1, a second via V2, a third via V3, a fourth via V4, a fifth via V5, a sixth via V6, a seventh via V7, an eighth via V8, and a ninth via V9.

In some examples, an orthographic projection of the first via V1 on the base substrate may be within a range of an orthographic projection of the first region 211 of the first active layer 21 on the base substrate. The third insulating layer, the second insulating layer, and the first insulating layer within the first via V1 may be etched away to expose a portion of a surface of the first region 211 of the first active layer 21, and the first via V1 may be configured such that a subsequently formed first connection electrode is connected with the first region 211 of the first active layer 21 through the via.

In some examples, an orthographic projection of the second via V2 on the base substrate may be within a range of an orthographic projection of the second region 212 of the first active layer 21 on the base substrate. The third insulating layer, the second insulating layer and the first insulating layer within the second via V2 may be etched away to expose a portion of a surface of the second region 212 of the first active layer 21. The second via V2 may be configured such that a subsequently formed second connection electrode is connected with the second region 212 of the first active layer 21 through the via.

In some examples, an orthographic projection of the third via V3 on the base substrate may be within a range of an orthographic projection of the first region 241 of the fourth active layer 24 on the base substrate. The third insulating layer, the second insulating layer and the first insulating layer within the third via V3 may be etched away to expose a portion of a surface of the first region 241 of the fourth active layer 24. The third via V3 may be configured so that a subsequently formed third connection electrode is connected to the first region 241 of the fourth active layer 24 through the via.

In some examples, an orthographic projection of the fourth via V4 on the base substrate may be within a range of an orthographic projection of the first region 251 of the fifth active layer 25 on the base substrate. The third insulating layer, the second insulating layer and the first insulating layer in the fourth via V4 may be etched away to expose a portion of a surface of the first region 251 of the fifth active layer 25. The fourth via V4 may be configured so that a subsequently formed fourth connection electrode is connected to the first region 251 of the fifth active layer 25 through the via.

In some examples, an orthographic projection of the fifth via V5 on the base substrate may be within a range of an orthographic projection of the second region 262 of the sixth active layer 26 on the base substrate. The third insulating layer, the second insulating layer and the first insulating layer within the fifth via V5 may be etched away to expose a portion of a surface of the second region 262 of the sixth active layer 26. The fifth via V5 may be configured so that a subsequently formed fifth connection electrode is connected to the second region 262 of the sixth active layer 26 through the via.

In some examples, an orthographic projection of the sixth via V6 on the base substrate may be within a range of an orthographic projection of the second region 272 of the seventh active layer 27 on the base substrate. The third insulating layer, the second insulating layer and the first insulating layer within the sixth via V6 may be etched away to expose a portion of a surface of the second region 272 of the seventh active layer 27. The sixth via V6 may be configured so that a subsequently formed fifth connection electrode is connected to the second region 272 of the seventh active layer 27 through the via.

In some examples, an orthographic projection of the seventh via V7 on the base substrate may be within a range of an orthographic projection of the first electrode plate 281 on the base substrate. The third insulating layer and the second insulating layer in the seventh via V7 may be etched away to expose a portion of a surface of the first electrode plate 281. The seventh via V7 may be configured so that a second connection electrode formed subsequently is connected to the first electrode plate 281 through the via.

In some examples, an orthographic projection of the eighth via V8 on the base substrate may be within a range of an orthographic projection of the second electrode plate 282 on the base substrate. The third insulating layer and the second insulating layer in the eighth via V8 may be etched away to expose a portion of a surface of the second electrode plate 282. The eighth via V8 may be configured so that a subsequently formed fourth connection electrode is connected to the second electrode plate 282 through the via.

In some examples, an orthographic projection of the ninth via V9 on the base substrate may be within a range of an orthographic projection of the initial connection block 34-1 of the first initial signal line 34 on the base substrate. The third insulating layer in the ninth via V9 may be etched away to expose a portion of a surface of the initial connection block 34-1. The ninth via V9 may be configured so that a first connection electrode formed subsequently is connected to the initial connection block 34-1 through the via.
(1-6) The third conductive layer is formed. In some examples, a third conductive thin film is deposited on the base substrate on which the above-mentioned patterns are formed, and the third conductive thin film is patterned through a patterning process to form a third conductive layer disposed on the third insulating layer. In some examples, the third conductive layer may also be referred to as a first source-drain metal layer.

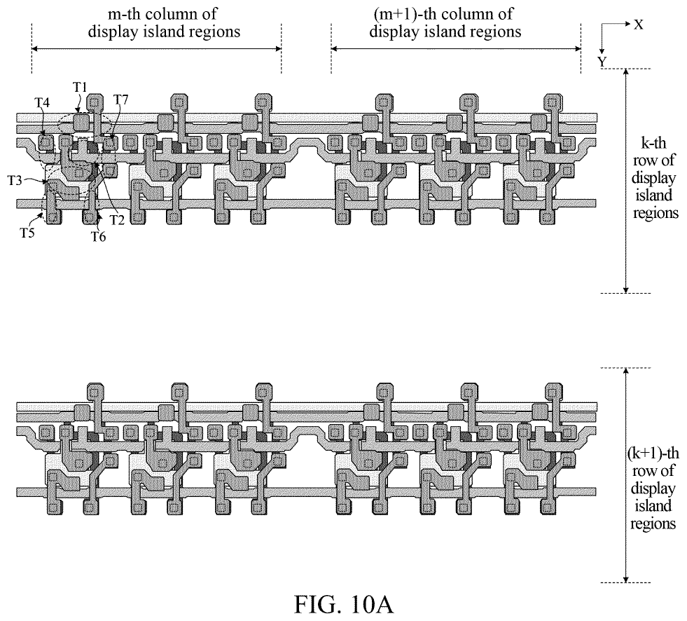

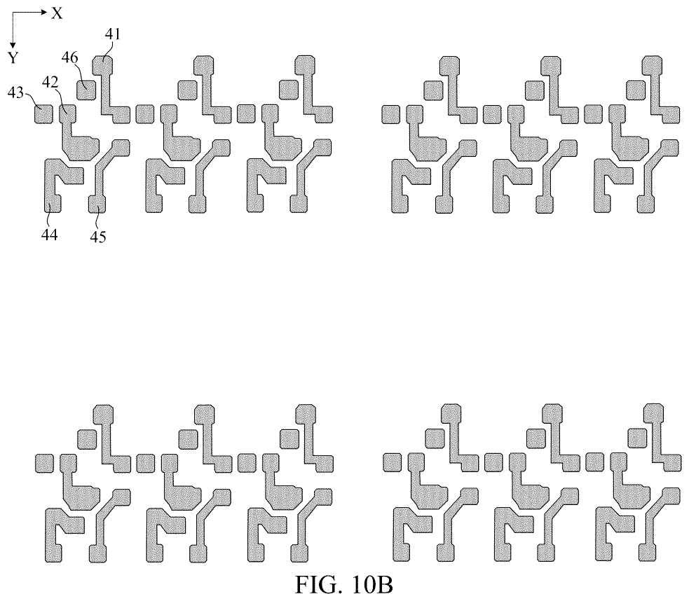

FIG. 10A is a schematic diagram of the display substrate after a third conductive layer is formed in FIG. 5. FIG. 10B is a schematic diagram of a third conductive layer in FIG. 10A. In some examples, as shown in FIGS. 10A and 10B, the third conductive layer of a single display island region of the first display region may include at least a first connection electrode 41, a second connection electrode 42, a third connection electrode 43, a fourth connection electrode 44, a fifth connection electrode 45, and a sixth connection electrode 46.

In some examples, the first connection electrode 41 may be substantially L-shaped. The first connection electrode 41 may be connected to the first region 211 of the first active layer 21 through the first via V1 and may be connected to the initial connection block 34-1 through the ninth via V9. Because the initial connection block 34-1 is connected to the first initial signal line 34, a first initial signal transmitted by the first initial signal line 34 can be provided to the first transistor T1 and the seventh transistor T7 through the first connection electrode 41.

In some examples, the second connection electrode 42 may be generally L-shaped. The second connection electrode 42 may be connected to the second region 212 of the first active layer 21 of the first transistor T1 through the second via V2, and may also be electrically connected to the first electrode plate 281 through the seventh via V7. The second connection electrode 42 may realize the electrical connection between the first transistor, the second transistor, the third transistor and the first electrode plate 281 of the storage capacitor, which may form a first node of the first pixel circuit.

In some examples, the third connection electrode 43 may be substantially in a shape of a rectangle, e.g., a rounded rectangle. The third connection electrode 43 may be connected to the first region 241 of the fourth active layer 24 of the fourth transistor T4 through the third via V3.

In some examples, the fourth connection electrode 44 may be substantially 7-shaped. The fourth connection electrode 44 may be connected to the first region 251 of the fifth active layer 25 of the fifth transistor T5 through the fourth via V4, and may also be connected to the second electrode plate 282 through the eighth via V8.

In some examples, the fifth connection electrode 45 may be substantially in a shape of a bending line. The fifth connection electrode 45 may be connected to the second region 262 of the sixth active layer 26 of the sixth transistor T6 through the fifth via V5, and may also be connected to the second region 272 of the seventh active layer 27 of the seventh transistor T7 through the sixth via V6.

In some examples, the sixth connection electrode 46 may be substantially in a shape of a rectangle, e.g., a rounded rectangle. The sixth connection electrode 46 may be located at a side of the first connection electrode 41 in the first direction X. An orthographic projection of the sixth connection electrode 46 on the base substrate may partially overlap orthographic projections of both the first initial signal line 34 and the second scan line 32 on the base substrate. The sixth connection electrode 46 may be configured to be electrically connected to the first power supply connection line through a fifteenth via formed subsequently.
(1-7) A fourth insulation layer is formed. In some examples, a fourth insulating thin film is deposited on the base substrate on which the above-mentioned patterns are formed, and the fourth insulating thin film is patterned through a patterning process to form a fourth insulating layer. The fourth insulating layer may be provided with a plurality of vias. In some examples, the fourth insulating layer may also be referred to as a passivation layer.

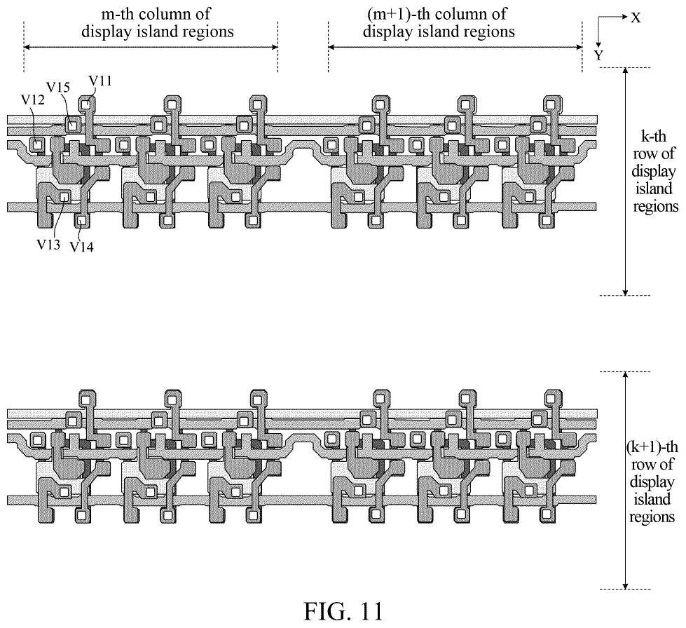

FIG. 11 is a schematic diagram of the display substrate after a fourth insulating layer is formed in FIG. 5. In some examples, the plurality of vias of the fourth insulating layer of a single display island region may include at least an eleventh via V11, a twelfth via V12, a thirteenth via V13, a fourteenth via V14, and a fifteenth via V15.

In some examples, an orthographic projection of the eleventh via V11 on the base substrate may be within a range of an orthographic projection of the first connection electrode 41 on the base substrate. The fourth insulating layer in the eleventh via V11 may be removed to expose a portion of a surface of the first connection electrode 41. The eleventh via V11 may be configured so that a first conductive block formed subsequently is connected to the first connection electrode 41 through the via.

In some examples, an orthographic projection of the twelfth via V12 on the base substrate may be within a range of an orthographic projection of the third connection electrode 43 on the base substrate. The fourth insulating layer in the twelfth via V12 may be removed to expose a portion of a surface of the third connection electrode 43. The twelfth via V12 may be configured so that a data line formed subsequently is connected to the third connection electrode 43 through the via.

In some examples, an orthographic projection of the thirteenth via V13 on the base substrate may be within a range of an orthographic projection of the fourth connection electrode 44 on the base substrate. The fourth insulating layer in the thirteenth via V13 may be removed to expose a portion of a surface of the fourth connection electrode 44. The thirteenth via V13 may be configured so that a first power supply connection portion of the first power supply connection line formed subsequently is connected to the fourth connection electrode 44 through the via.

In some examples, an orthographic projection of the fourteenth via V14 on the base substrate may be within a range of an orthographic projection of the fifth connection electrode 45 on the base substrate. The fourth insulating layer in the fourteenth via V14 may be removed to expose a portion of a surface of the fifth connection electrode 45. The fourteenth via V14 may be configured so that a first anode connection electrode formed subsequently is connected to the fifth connection electrode 45 through the via.

In some examples, an orthographic projection of the fifteenth via V15 on the base substrate may be within a range of an orthographic projection of the sixth connection electrode 46 on the base substrate. The fourth insulating layer in the fifteenth via V15 may be removed to expose a portion of a surface of the sixth connection electrode 46. The fifteenth via V15 may be configured so that a second power supply connection portion of the first power supply connection line formed subsequently is connected to the sixth connection electrode 46 through the via.
(1-8) A transparent conductive layer is formed. In some examples, a transparent conductive thin film is deposited on the base substrate on which the above-mentioned patterns are formed, and the transparent conductive thin film is patterned through a patterning process to form a transparent conductive layer disposed on the fourth insulating layer.

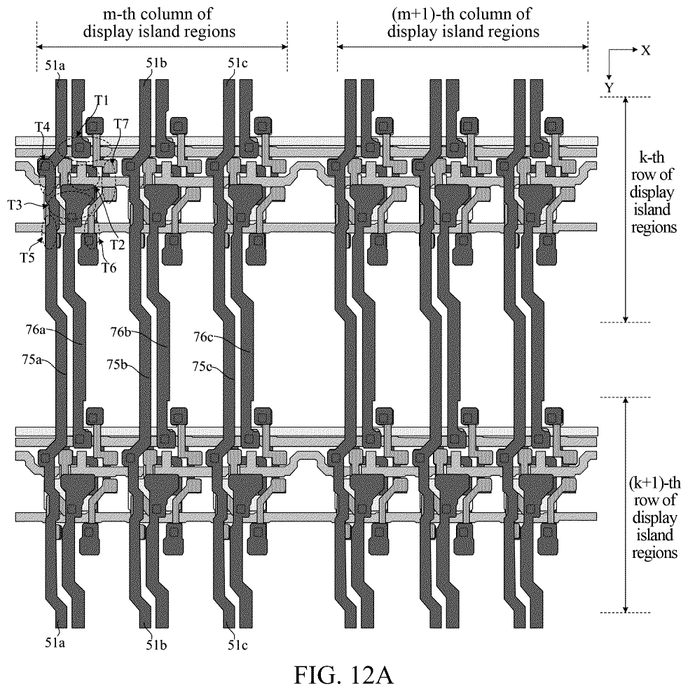

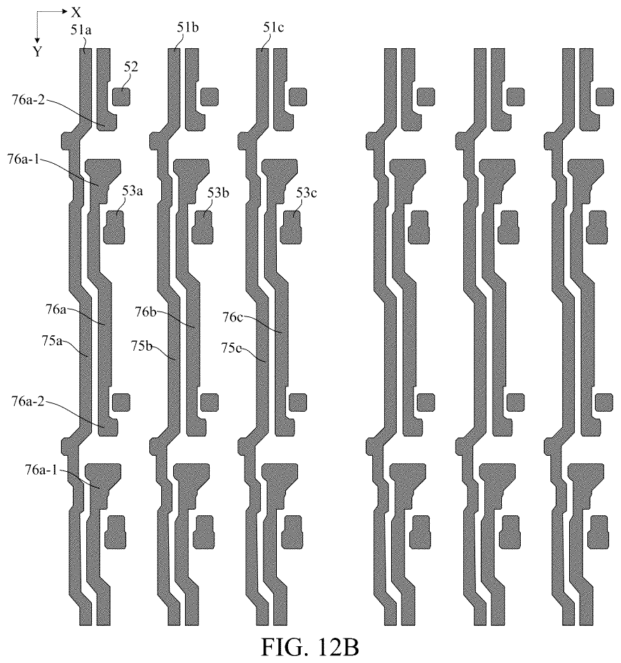

FIG. 12A is a schematic diagram of the display substrate after a transparent conductive layer is formed in FIG. 5. FIG. 12B is a schematic diagram of the transparent conductive layer in FIG. 12A. In some examples, as shown in FIGS. 12A and 12B, the transparent conductive layer of a single display island region of the first display region may include at least three data lines (e.g. including data lines 51a, 51b and 51c), three first conductive blocks 52, and three first anode connection electrodes (e.g. including first anode connection electrodes 53a, 53b and 53c).

In some examples, each data line in the display island region may be substantially same in shape, for example, may be in a shape of a bending line in which a main portion extends in the second direction Y. The three data lines 51a, 51b and 51c may be arranged sequentially in the first direction X. The extension directions of the three data lines 51a, 51b and 51c may be substantially parallel. The data line 51a may be electrically connected to the third connection electrode 43 of a first first pixel circuit through the twelfth via V12 to be configured to provide a data signal to a first electrode of the fourth transistor T4 of the first first pixel circuit. The data line 51b may be configured to provide a data signal to a first electrode of the fourth transistor of a second first pixel circuit. The data line 51c may be configured to provide a data signal to a first electrode of the fourth transistor of a third first pixel circuit.

In some examples, the three first conductive blocks 52 in the display island region may be substantially same in shape, for example, all in a shape of a rectangle, e.g., may be in a shape of a rounded rectangle. The first conductive block 52 may be electrically connected to the first connection electrode 41 through the eleventh via V11. The first conductive block 52 is not electrically connected to a conductive thin film layer prepared subsequently. The first conductive block 52 may be connected in parallel with the first connection electrode 41 and the resistance of the first connection electrode 41 may be reduced thereby ensuring the transmission quality of the first initial signal. In other examples, the provision of the first conductive block may be omitted.

In some examples, the three first anode connection electrodes in the display island region may be substantially same in shape, for example, may be substantially rectangular. The first anode connection electrode 53a may be located between the data lines 51a and 51b, the first anode connection electrode 53b may be located between the data lines 51b and 51c, and the first anode connection electrode 53c may be located at a side of the data line 51c away from the data line 51b. The first anode connection electrode 53a may be connected to the fifth connection electrode 45 of the first first pixel circuit through the fourteenth via V14, and the first anode connection electrode 53a may be configured to be electrically connected to an anode of a first first light emitting element formed subsequently, thereby achieving the electrical connection of the first first pixel circuit to the first first light emitting element. The first anode connection electrode 53b may be configured to be electrically connected with the fifth connection electrode of the second first pixel circuit to subsequently achieve the electrical connection of the second first pixel circuit and a second first light emitting element. The first anode connection electrode 53c may be configured to be electrically connected with the fifth connection electrode of the third first pixel circuit to subsequently achieve the electrical connection of the third first pixel circuit and a third first light emitting element.

In some examples, the transparent conductive layer of the first light transmitting region between display island regions adjacent in the second direction Y may include at least a plurality of first power supply connection lines (e.g. including first power supply connection lines 76a, 76b, and 76c), a plurality of data connection lines (e.g. including data connection lines 75a, 75b, and 75c). The plurality of data connection lines and the plurality of first power supply connection lines can be arranged at intervals. The plurality of data connection lines and the plurality of first power supply connection lines may substantially be in a shape of a bending line in which a main portion extends in the second direction Y.

In some examples, data lines 51a in display island regions adjacent in the second direction Y may be connected by the data connection line 75a. A first end of the data connection line 75a is connected to the data line 51a in one display island region and a second end thereof is connected to the data line 51a in the other display island region. Data lines 51b in adjacent display island regions may be connected by the data connection line 75b. Data lines 51c in adjacent display island regions may be connected by the data connection line 75c. The data connection line and the connected data line can be of an interconnected integral structure.

In some examples, the first power supply connection line may be located between two adjacent data lines. The spacing between the first power supply connection line 76a and the data line 75a may be smaller than the spacing between the first power supply connection line 76a and the data line 75b. The first power supply connection line can extend into the display island region in the second direction Y.

In some examples, the first power supply connection line 76a may have a first power supply connection portion 76a-1 and a second power supply connection portion 76a-2. The first power supply connection portion 76a-1 of the first power supply connection line 76a may be electrically connected to the fourth connection electrode of the first first pixel circuit through the thirteenth via V13 in the display island region, so as to be configured to provide a first voltage signal to the storage capacitor and the fifth transistor of the first first pixel circuit. The second power supply connection portion 76a-2 of the first power supply connection line 76a may extend to the other display island region and is electrically connected to the sixth connection electrode of the first first pixel circuit in the other display island region through the fifteenth via V15. The second power supply connection line 76b may be configured to provide a first voltage signal to the second first pixel circuit of the display island region. The second power supply connection line 76c may be configured to provide a first voltage signal to the third first pixel circuit of the display island region.
(1-9) The fifth insulation layer is formed. In some examples, a fifth insulating thin film is coated on the base substrate on which the above-mentioned patterns are formed, and the fifth insulating thin film is patterned through a patterning process to form a fifth insulating layer. The fifth insulating layer may be provided with a plurality of vias. In some examples, the fifth insulating layer may also be referred to as a first planarization layer.

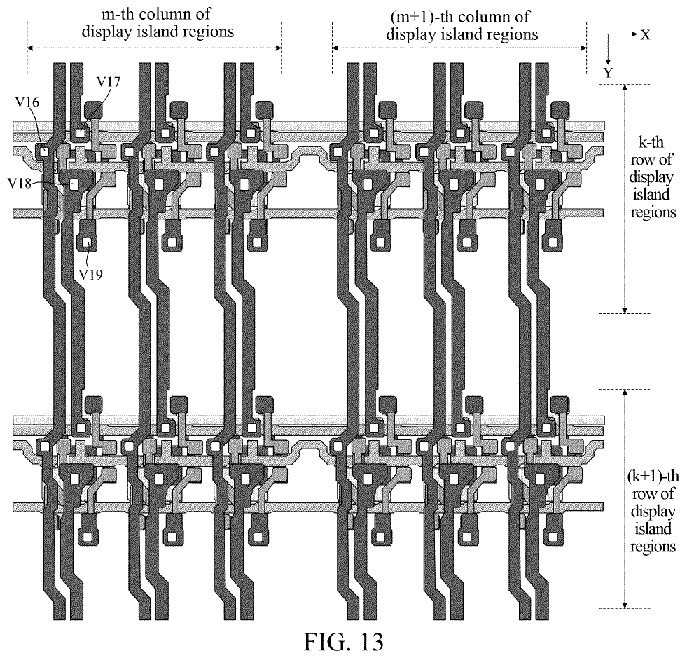

FIG. 13 is a schematic view of a display substrate after a fifth insulation layer is formed in FIG. 5.

In some examples, the plurality of vias of the fifth insulating layer of a single display island region may include at least a sixteenth via V16, a seventeenth via V17, an eighteenth via V18, and a nineteenth via V19.

In some examples, an orthographic projection of the sixteenth via V16 on the base substrate may be within a range of an orthographic projection of the data line 51a on the base substrate. The fifth insulating layer in the sixteenth via V16 may be removed to expose a portion of a surface of the data line 51a. The sixteenth via V16 may be configured so that a second conductive block formed subsequently is connected to the data line 51a through the via.

In some examples, an orthographic projection of the seventeenth via V17 on the base substrate may be within an orthographic projection of the second power supply connection portion 76a-2 of one first power supply connection line on the base substrate. The fifth insulating layer in the seventeenth via V17 can be removed to expose a portion of a surface of the second power supply connection portion 76a-2 of one first power supply connection line. The seventeenth via V17 may be configured so that a second power supply connection line formed subsequently is connected to the second power supply connection portion 76a-2 of one first power supply connection line through the via.

In some examples, an orthographic projection of the eighteenth via V18 on the base substrate may be within a range of an orthographic projection of the first power supply connection portion 76a-1 of another first power supply connection line on the base substrate. The fifth insulating layer in the eighteenth via V18 may be removed to expose a portion of a surface of the first power supply connection portion 76a-1 of the other first power supply connection line. The eighteenth via V18 may be configured so that a second power supply connection line formed subsequently is connected to the first power supply connection portion 76a-1 of the other first power supply connection line through the via.

In some examples, an orthographic projection of the nineteenth via V19 on the base substrate may be within a range of an orthographic projection of the first anode connection electrode 53a on the base substrate. The fifth insulating layer in the nineteenth via V19 may be removed to expose a portion of a surface of the first anode connection electrode 53a. The nineteenth via V19 may be configured so that a second anode connection electrode formed subsequently is connected to the first anode connection electrode 53a through the via.
(1-10) The fourth conductive layer is formed. In some examples, a fourth conductive thin film is deposited on the base on which the aforementioned patterns are formed, and the fourth conductive thin film is patterned through a patterning process to form a fourth conductive layer disposed on the fifth insulating layer. In some examples, the fourth conductive layer may also be referred to as a second source-drain metal layer.

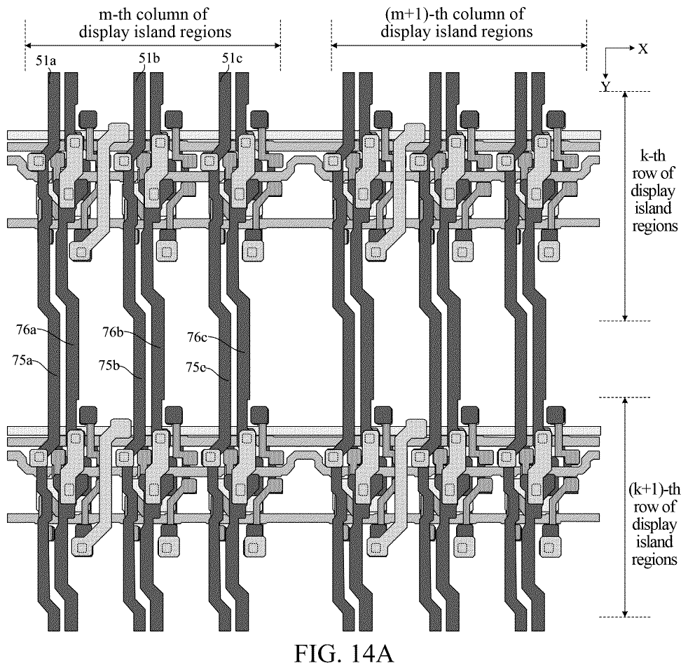

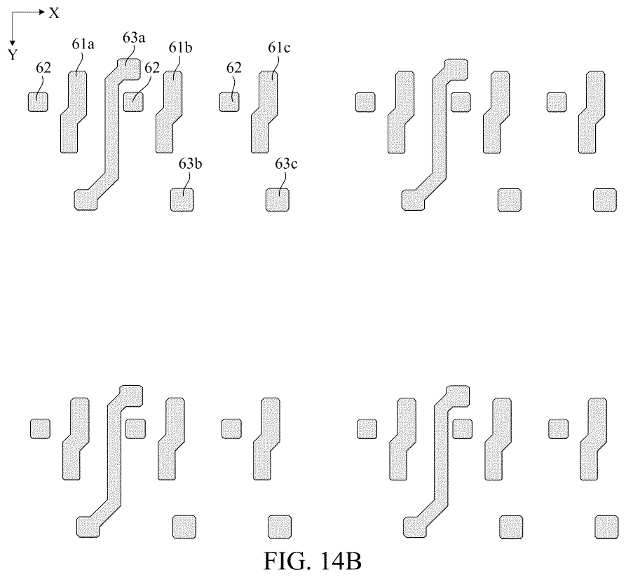

FIG. 14A is a schematic diagram of the display substrate after a fourth conductive layer is formed in FIG. 5. FIG. 14B is a schematic diagram of a fourth conductive layer in FIG. 14A. In some examples, as shown in FIGS. 14A and 14B, the fourth conductive layer of a single display island region of the first display region may include at least three second power supply connection lines (e.g. including second power supply connection lines 61a, 61b and 61c), three second conductive blocks 62, and three second anode connection electrodes (e.g. including second anode connection electrodes 63a, 63b and 63c).

In some examples, the three second conductive blocks 62 and the three second power supply connection lines may arranged at intervals in the first direction X. The second anode connection electrode 63a may be located between a second conductive block 62 and the second power supply connection line 61a in the first direction X. The second anode connection electrodes 63b and 63c may be located at a side of the second power supply connection lines 61b and 61c in the second direction Y.

In some examples, the three second conductive blocks 62 may be substantially same in shape, for example, may be substantially in a shape of a rectangle, for example, may be in a shape of a rounded rectangle. The three second conductive blocks 62 may be electrically connected to the three data lines in one-to-one correspondence. For example, a second conductive block 62 may be electrically connected to the data line 51a through the sixteenth via V16. By connecting the second conductive block 62 in parallel with a corresponding data line, the resistance of the data line can be reduced, thereby ensuring the transmission quality of the data signal. In other examples, the provision of the second conductive block may be omitted.

In some examples, the three second power supply connection lines may be substantially same in shape, for example, may be substantially in a shape of a bending line in which a main portion extends in the second direction Y. The extension directions of the three second power supply connection lines can be substantially parallel. The three second power supply connection lines can be arranged in the three first pixel circuits sequentially. The second power supply connection line 61a may be connected to the second power supply connection portion 76a-2 of one first power supply connection line 76a through the seventeenth via V17, and may be connected to the first power supply connection portion 76a-1 of another first power supply connection line 76a through the eighteenth via V18. The first power supply connection line 61a can enable longitudinal transmission of the first voltage signal within the first first pixel circuit. The first power supply connection line 61b may enable longitudinal transmission of the first voltage signal within the second first pixel circuit. The first power supply connection line 61c may enable longitudinal transmission of the first voltage signal within the third first pixel circuit.

In some examples, the second anode connection electrode 63a may be substantially in a shape of a bending line in which a main portion extends in the second direction Y. The second anode connection electrode 63a may be electrically connected to the first anode connection electrode 53a through the nineteenth via V19. In this example, the electrical connection of the first first pixel circuit and the first first light emitting element can be achieved through the first anode connection electrode 53a and the second anode connection electrode 63a. In this example, the position of the first light emitting element can be changed by adjusting the shape and position of the second anode connection electrode 63a.

In some examples, the second anode connection electrodes 63b and 63c may be substantially same in shape, for example, they may both be substantially rectangular. The second anode connection electrode 63b may be electrically connected to the first anode connection electrode 53b so as to subsequently achieve the electrical connection of the second first pixel circuit to the second first light emitting element. The second anode connection electrode 63c may be electrically connected to the first anode connection electrode 53c so as to subsequently achieve the electrical connection of the third first pixel circuit to the third first light emitting element.
(1-11) A sixth insulation layer is formed. In some examples, a sixth insulating thin film is coated on the base on which the aforementioned patterns are formed, and the sixth insulating thin film is patterned through a patterning process to form a sixth insulating layer. The sixth insulating layer may be provided with a plurality of vias. In some examples, the sixth insulating layer may also be referred to as a second planarization layer.

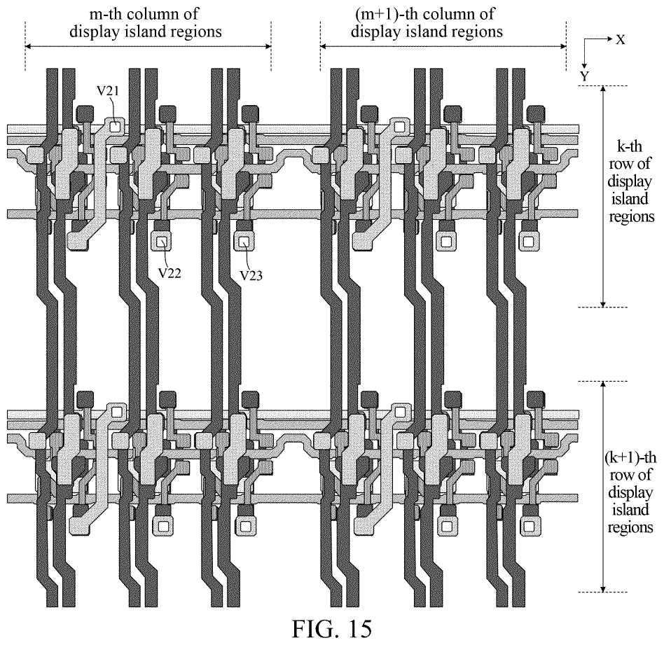

FIG. 15 is a schematic view of a display substrate after a sixth insulation layer is formed in FIG. 5. In some examples, the plurality of vias of the sixth insulating layer of a single display island region may include at least a twenty-first via V21, a twenty-second via V22, and a twenty-third via V23.

In some examples, an orthographic projection of the twenty-first via V21 on the base substrate may be within a range of an orthographic projection of the second anode connection electrode 63a on the base substrate. The sixth insulating layer in the twenty-first via V21 may be removed to expose a portion of a surface of the second anode connection electrode 63a. The twenty-first via V21 may be configured so that an anode of a first first light emitting element formed subsequently is connected to the second anode connection electrode 63a through the via.

In some examples, an orthographic projection of the twenty-second via V22 on the base substrate may be within a range of an orthographic projection of the second anode connection electrode 63b on the base substrate. The sixth insulating layer in the twenty-second via V22 may be removed to expose a portion of a surface of the second anode connection electrode 63b. The twenty-second via V22 may be configured so that an anode of a second first light emitting element formed subsequently is connected to the second anode connection electrode 63b through the via.

In some examples, an orthographic projection of the twenty-third via V23 on the base substrate may be within a range of an orthographic projection of the second anode connection electrode 63c on the base substrate. The sixth insulating layer in the twenty-third via V23 may be removed to expose a portion of a surface of the second anode connection electrode 63c. The twenty-third via V23 may be configured so that an anode of a first first light emitting element formed subsequently is connected to the second anode connection electrode 63c through the via.

In some examples, after the formation of the sixth insulating layer, the first line region may include a base substrate, a first insulating layer, a first conductive layer (e.g. including a first scan connection line 71, a second scan connection line 72, and a light emitting control connection line 73), a second insulating layer, a second conductive layer (e.g. including a first initial connection line 74), a third insulating layer, a fourth insulating layer, a fifth insulating layer, and a sixth insulating layer sequentially disposed on the base substrate.

In some examples, after the formation of the sixth insulating layer, the first light transmitting region may include a base substrate, a first insulating layer, a second insulating layer, a third insulating layer, a fourth insulating layer, a transparent conductive layer (including, for example, a first power supply connection line and a data connection line), a fifth insulating layer, and a sixth insulating layer arranged on the base substrate sequentially.

In some examples, after the formation of the sixth insulating layer, the second light transmitting region may include a base substrate, a first insulating layer, a second insulating layer, a third insulating layer, a fourth insulating layer, a fifth insulating layer, and a sixth insulating layer disposed on the base substrate sequentially.

In this example, a first signal line connecting first pixel circuits in adjacent display island regions may include a first scan connection line, a second scan connection line and a light emitting control connection line located in the first conductive layer, and a first initial connection line located in the second conductive layer. A second signal line connecting first pixel circuits in adjacent display island regions may include a first power supply connection line and a data connection line located in the transparent conductive layer.
(1-12) An anode layer is formed. In some examples, an anode thin film is deposited on the base on which the aforementioned patterns are formed, and the anode thin film is patterned through a patterning process to form an anode layer.

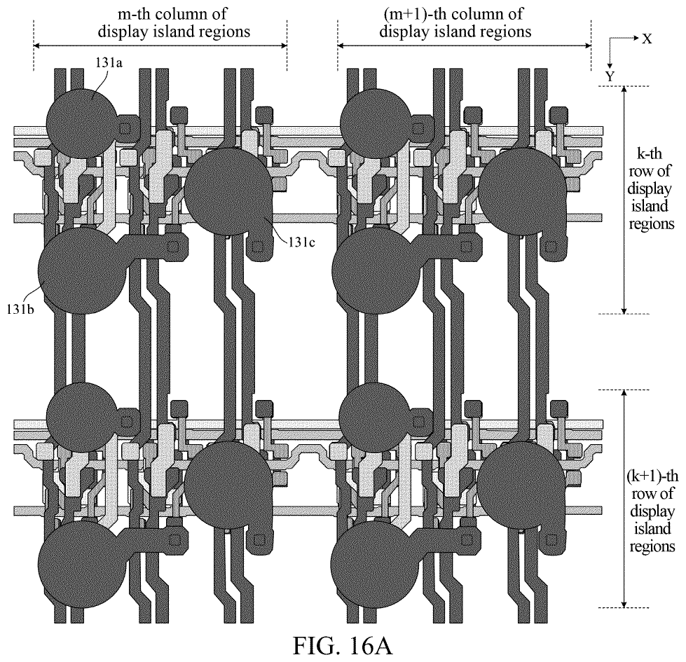

FIG. 16A is a schematic diagram of the display substrate after an anode layer is formed in FIG. 5. FIG. 16B is a schematic diagram of the anode layer in FIG. 16A. In some examples, as shown in FIGS. 16A and 16B, the anode layer of a single display island region may include at least three anodes (e.g. including anodes 131a, 131b and 131c).

In some examples, the anodes 131a, 131b and 131c may be substantially same in shape, for example, all of them are circular or elliptical. The area of the anode 131a may be smaller than the area of the anode 131b and smaller than the area of the anode 131c. The areas of the anodes 131b and 131c may be substantially the same.

In some examples, a side of the anode 131a close to the anode 131c may be provided with an anode connection block 131a-1. The anode connection block 131a-1 may be provided in the first first pixel circuit. A first end of the anode connection block 131a-1 is connected to the anode 131a and a second end thereof extends toward a direction away from the anode 131a in the first direction X. The anode connection block 131a-1 may be electrically connected to the second anode connection electrode 63a through the twenty-first via V21. The anode connection block 131a-1 and the anode 131a may be of an interconnected integral structure.

In some examples, a side of the anode 131b close to the anode 131c may be provided with an anode connection block 131b-1. At least part of the anode connection block 131b-1 may be disposed in the second first pixel circuit. A first end of the anode connection block 131b-1 is connected to the anode 131b and a second end thereof extends towards a direction away from the anode 131b in the first direction X. The anode connection block 131b-1 may be electrically connected to the second anode connection electrode 63b through the twenty-second via V22. The anode connection block 131b-1 and the anode 131b may be of an interconnected integral structure.

In some examples, a side of the anode 131c close to the anode 131b may be provided with an anode connection block 131c-1. The anode connection block 131c-1 may be provided in the third first pixel circuit. A first end of the anode connection block 131c-1 is connected to the anode 131c and a second end thereof extends towards a direction away from the anode 131c in the second direction Y. The anode connection block 131c-1 may be electrically connected to the second anode connection electrode 63c through the twenty-third via V23. The anode connection block 131c-1 and the anode 131c may be of an interconnected integral structure.
(1-13) A pixel define layer is formed. In some examples, a pixel define thin film is coated on the base on which the aforementioned patterns are formed, and a pixel define layer (PDL) is formed by processes of masking, exposure and development.

In some examples, as shown in FIG. 5, the pixel define layer of a single display island region may form three pixel openings (e.g. including a first pixel opening OP1, a second pixel opening OP2, and a third pixel opening OP3). The first pixel opening OP1 may expose a portion of a surface of the anode 131a, the second pixel opening OP2 may expose a portion of a surface of the anode 131b, and the third pixel opening OP3 may expose a portion of a surface of the anode 131c.

In some examples, the pixel define layer of the first display region may be made of black material. The black pixel define layer can absorb stray light to reduce diffraction influence and optimize photographing effect. For example, the pixel define layers of the first and second light transmitting regions may be removed to ensure light transmittance. The pixel define layer of the first line region can be retained to shade the lines in the first line region, so as to avoid diffraction conditions due to light transmission. However, the embodiment is not limited thereto. In other examples, the display substrate may shield the first line region by providing a Black Matrix (BM). In other examples, the display substrate may be provided with a Bottom Shielding Metal (BSM) to shield the display island region and the first line region, and the bottom shielding metal may be located on a side of the semiconductor layer close to the base substrate.
(1-14) An organic light emitting layer, a cathode layer and an encapsulation layer are formed. In some examples, organic light emitting layers may be respectively formed within the plurality of pixel openings formed as described above, and the organic light emitting layers are connected to corresponding anodes. Subsequently, a cathode thin film is deposited, and the cathode thin film is patterned through a patterning process to form a cathode layer, and the cathode layer may be electrically connected to the organic light emitting layer and the second power supply line, respectively. Then, an encapsulation layer is formed on the cathode layer. The encapsulation layer may include a stacked structure of an inorganic material/an organic material/an inorganic material.

In some examples, the first conductive layer, the second conductive layer, the third conductive layer, and the fourth conductive layer may be made of a metal material, such as any one or more of Silver (Ag), Copper (Cu), Aluminum (Al), and Molybdenum (Mo), or an alloy material of the aforementioned metals, such as an Aluminum Neodymium alloy (AlNd) or a Molybdenum Niobium alloy (MoNb), and may be of a single-layer structure or a multi-layer composite structure, such as Mo/Cu/Mo. The transparent conductive layer may be made of a transparent conductive material, such as Indium Tin Oxide (ITO). The first to fourth insulating layers may be made of any one or more of a silicon oxide (SiOx, x>0), a silicon nitride (SiNy, y>0) and a silicon oxynitride (SiON), and may be in a single layer, a plurality of layers, or a composite layer. The fifth insulating layer and the sixth insulating layer may be made of an organic material such as polyimide, acrylic or polyethylene terephthalate. The pixel define layer may be made of an organic material, such as polyimide, acrylic, or polyethylene terephthalate. The anode layer may be made of a reflective material such as a metal and the cathode layer may be made of a transparent conductive material. However, the embodiment is not limited thereto.

In some examples, as shown in FIG. 1, the second display region A2 may include a plurality of second pixel circuits 12 and a plurality of second light emitting elements 14. At least one second pixel circuit 12 may be electrically connected to at least one second light emitting element 14, and the at least one second pixel circuit 12 may be configured to drive the electrically connected at least one second light emitting element 14 to emit light. For example, the plurality of second pixel circuits 12 and the plurality of second light emitting elements 14 may be electrically connected in one-to-one correspondence. The plurality of second light emitting elements 14 of the second display region A2 may include a second light emitting element emitting light of a first color, a second light emitting element emitting light of a second color, and a second light emitting element emitting light of a third color. The arrangement of the plurality of second light emitting elements may be similar to that of the plurality of first light emitting elements, and will not be repeated here. In some examples, an orthographic projection of a light emitting region of a second light emitting element on the base substrate may overlap an orthographic projection of an electrically connected second pixel circuit on the base substrate. In some examples, an electrical connection between adjacent second pixel circuits of the second display region may be achieved without the need of lines of the transparent conductive layer, and the second display region may be not required to be provided with a transparent conductive layer. The rest of the film structure of the second display region may be similar to the film structure of the first display region, and will not be repeated here.

A structure and a manufacturing process of the display substrate of this embodiment are merely illustrative. In some examples, a corresponding structure may be changed and a patterning process may be added or reduced according to actual needs. The manufacturing process of the exemplary embodiment may be implemented using an existing mature manufacturing device, and may be compatible well with an existing manufacturing process, simple in process implementation, easy to implement, high in a production efficiency, low in a production cost, and high in yield.

In some implementations, a single display island region of the first display region may be provided with one first light emitting element and one first pixel circuit, and the first pixel circuit may be located below the first light emitting element such that the light transmitting region is as large as possible. However, when a single first pixel circuit is disposed in the display island region, the spacing between the display island regions is small, and the winding space for the electrically connecting between the first signal line and the second signal line in adjacent first pixel circuits can be limited, resulting in the first signal line and the second signal line being longer, and the line width and line spacing being smaller. When the first signal line and the second signal line are made of a transparent conductive material, taking the transparent conductive material being ITO as an example, due to the larger square resistance of ITO, the load of the longer first signal line and the longer second signal line are larger, which will affect the display effect and cause display defect. Compared to a scheme in which one first light emitting element and one first pixel circuit are provided in a single display island region and the first pixel circuit is covered by the first light emitting element, the display substrate according to the present embodiment, by centrally arranging a plurality of first pixel circuits and a plurality of first light emitting elements in a display island region, can increase the space between adjacent display island regions, increase the freedom of arrangement of the second signal lines located in the transparent conductive layer, increase the wiring space of the second signal lines, allow increasing the line width of the second signal line, to reduce the resistance of the second signal line, avoid the display defect of the display substrate due to the load of the second signal line, and allow support for a higher refresh rate.

The use of a metal material for the first signal line of the display substrate of the present embodiment can reduce the cost of the mask using the transparent conductive layer, and can reduce the lateral display defect caused by the resistance of the first signal line. In addition, the spacing between display island regions adjacent in the first direction can be reduced by setting the first signal line to be made of a metal material, and the size of a display island region in the second direction can be reduced by increasing the size of the display island region in the first direction on the basis of ensuring the total size of the first pixel circuit, thereby increasing the spacing between display island regions adjacent in the second direction and increasing the light transmittance of the second light transmitting region. Moreover, by setting the first signal line to be made of a metal material, the punching process between display island regions adjacent in the first direction can be avoided, the occupied space of the first signal lines can be reduced, and the cost can be reduced.

In addition, in a scheme in which one first light emitting element and one first pixel circuit are provided in a single display island region and the first pixel circuit is covered by the first light emitting element, there are more raised display isolated islands and recessed slits, which tends to exacerbate the light diffraction effect in the first display region and reduces the photographing image quality. The display substrate provided in this embodiment, by centrally arranging a plurality of first pixel circuits in the display island region, can reduce the quantities of isolated islands and slits, increase the size of a light transmitting region between adjacent display island regions, effectively reduce the light diffraction effect, and facilitate smooth processing on the edge of the display island region.

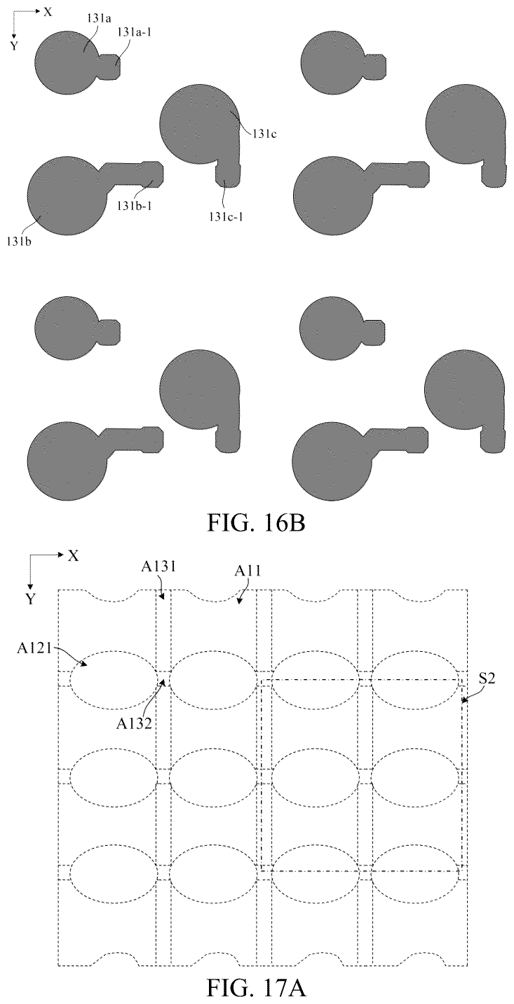

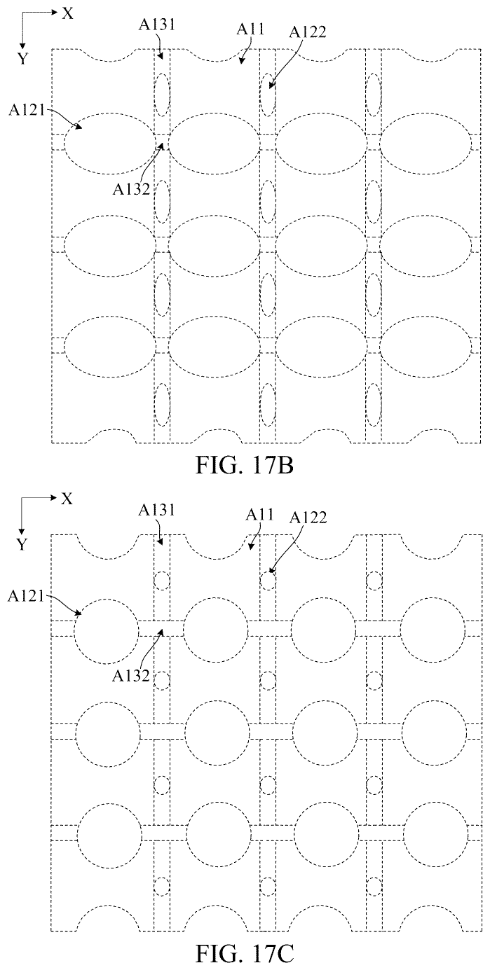

FIG. 17A is another schematic diagram of a first display region according to at least one embodiment of the present disclosure. In some examples, as shown in FIG. 17A, in a plane parallel to the display substrate, the first display region A1 may include a plurality of display island regions A11 arranged in an array. The plurality of display island regions A11 may be arranged in an array in the first direction X and the second direction Y. The shapes of the plurality of display island regions A11 may be substantially the same. For example, the display island region can be in an irregular shape with smooth edges. The display island region A11 has smooth edges, which can reduce the light diffraction effect and help to improve the photographing effect.

In some examples, as shown in FIG. 17A, a first light transmitting region A121 may be provided between adjacent display island regions A11. The first light transmitting region A121 may be located between adjacent display island regions A11 along the second direction Y. A plurality of first light transmitting regions A121 may be independently formed. Adjacent first light transmitting regions A121 may not be communicated. The plurality of first light transmitting regions A121 may be arranged in an array in the first direction X and the second direction Y. For example, the first light transmitting region A121 may be elliptical or may be in other shapes such as a rounded polygon.

In some examples, as shown in FIG. 17A, a line region may be provided between adjacent display island regions A11. For example, the line region may include a first line region A131 and a second line region A132. The first line region A131 may be located between display island regions A11 adjacent along the first direction X. The second line region A132 may be located between the first light transmitting regions A121 adjacent in the first direction X. The first line region A131 and the second line region A132 may communicate in the second direction Y. The plurality of second line regions A132 and the plurality of first light transmitting regions A121 may be arranged at intervals along the first direction X. Display island regions A11 adjacent in the first direction X may be communicated through the first line region A131, and display island regions A11 adjacent in the second direction Y may be communicated through the second line region A132.

FIG. 17B is another schematic diagram of a first display region according to at least one embodiment of the present disclosure. In some examples, as shown in FIG. 17B, in a plane parallel to the display substrate, the first display region A1 may include a plurality of display island regions A11 arranged in an array, a first light transmitting region A121 and a second light transmitting region A122 located between adjacent display island regions A11, and a first line region A131 and a second line region A132 located between adjacent display island regions A11. The first light transmitting region A121 may be located between display island regions A11 adjacent in the second direction Y, and the second light transmitting region A122 may be located between display island regions A11 adjacent in the first direction X. The second light transmitting region A122 may be surrounded by the first line region A131 or may be surrounded by the first line region A131 and the display island region A11. The first light transmitting region A121 may be surrounded by the second line region A132 and the display island region A11. The shapes of the first light transmitting region A121 and the second light transmitting region A122 may be substantially the same, for example, both may be elliptical. The area of a single first light transmitting region A121 may be larger than the area of a single second light transmitting region A122. However, the embodiment is not limited thereto. For example, the first and second light transmitting regions may be different in shape, for example, may be in different shapes with smooth edges. The description of the second light transmitting region can refer to the description of the foregoing embodiments.

FIG. 17C is another schematic diagram of a first display region according to at least one embodiment of the present disclosure. In some examples, as shown in FIG. 17C, in a plane parallel to the display substrate, the first display region A1 may include a plurality of display island regions A11 arranged in an array, a first light transmitting region A121 and a second light transmitting region A122 located between adjacent display island regions A11, and a first line region A131 and a second line region A132 located between adjacent display island regions A11. The shapes of the first light transmitting region A121 and the second light transmitting region A122 may be substantially the same, for example, they may both be circular. However, the embodiment is not limited thereto. In other examples, the shapes of the first and second light transmitting regions may be rounded rectangles, rounded polygons or other shapes having smooth edges. The remaining description of the display substrate of this example can refer to the description of the foregoing embodiments.

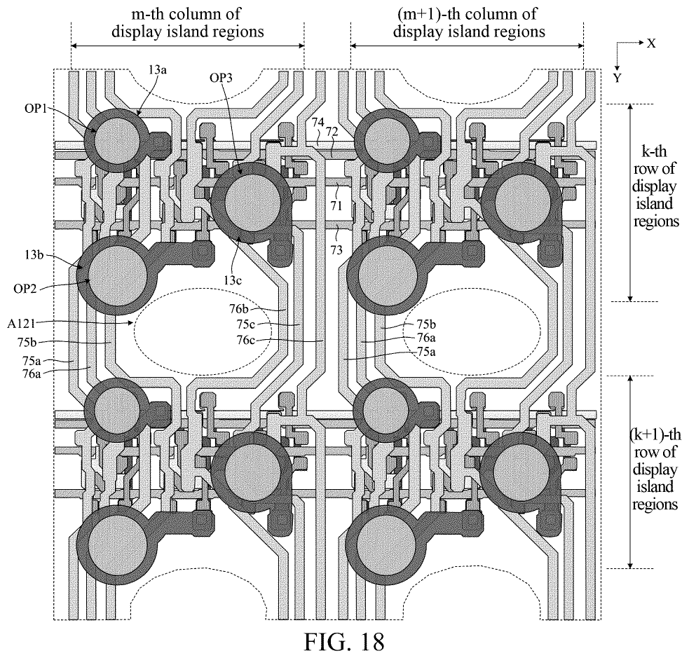

FIG. 18 is a schematic partial top view of the region S2 in FIG. 17A. Four display island regions A11 arranged in a 2×2 array are illustrated in FIG. 18.

In some examples, in a direction perpendicular to the display substrate, the circuit structure layer of the first display region may include a semiconductor layer, a first conductive layer, a second conductive layer, a third conductive layer, and a fourth conductive layer that are sequentially disposed on the base substrate. A first insulating layer may be provided between the semiconductor layer and the first conductive layer, a second insulating layer may be provided between the first conductive layer and the second conductive layer, a third insulating layer may be provided between the second conductive layer and the third conductive layer, a fourth insulating layer and a fifth insulating layer may be provided between the third conductive layer and the fourth conductive layer, and a sixth insulating layer may be provided on a side of the fourth conductive layer away from the base substrate.

Exemplary description is made below for a structure and a manufacturing process of a display substrate according to the present example. In some examples, the preparing process of the display substrate according to the present example may include following operations.
(2-1) The base substrate is provided.
(2-2) The semiconductor layer is formed. In some examples, a semiconductor thin film is deposited on the base substrate, and the semiconductor thin film is patterned through a patterning process to form a semiconductor layer disposed on the base substrate. In some examples, the semiconductor layers of a single display island region may include at least first active layers of first transistors, second active layers of second transistors, third active layers of third transistors, fourth active layers of fourth transistors, fifth active layers of fifth transistors, sixth active layers of sixth transistors, and seventh active layers of seventh transistors of the three first pixel circuits. The description of the semiconductor layer of the display substrate of the present example may refer to the description of the foregoing embodiments and therefore will not be repeated here.
(2-3) The first conductive layer is formed. In some examples, a first insulating thin film and a first conductive thin film are sequentially deposited on the base substrate on which the above-mentioned patterns are formed, and the first conductive thin film is patterned through a patterning process to form a first insulating layer disposed on the semiconductor layer and a first conductive layer disposed on the first insulating layer.

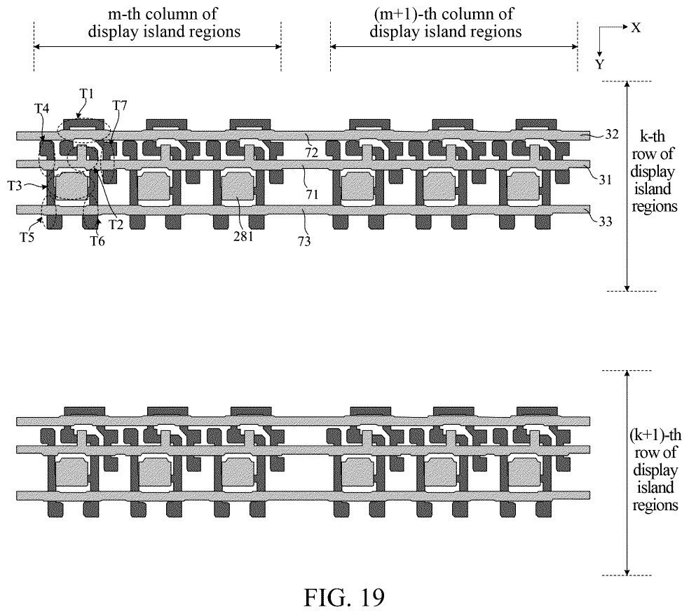

FIG. 19 is a schematic view of the display substrate after a first conductive layer is formed in FIG. 18. In some examples, as shown in FIG. 19, the first conductive layer of a single display island region may include at least a first scan line 31, a second scan line 32, a light emitting control line 33, and first electrode plates 281 of the storage capacitors of the three first pixel circuits. The first conductive layer of the first line region between display island regions adjacent in the first direction X may include at least a first scan connection line 71, a second scan connection line 72, and a light emitting control connection line 73. The first scan connection line 71, the second scan connection line 72 and the light emitting control connection line 73 may all be in a shape of a straight line in which a main portion extends in the first direction X. The rest of the description of the first conductive layer of the display substrate of this example may refer to the description of the foregoing embodiments, and will not be repeated here.
(2-4) The second conductive layer is formed. In some examples, a second insulating thin film and a second conductive thin film are sequentially deposited on the base substrate on which the above-mentioned patterns are formed, and the second conductive thin film is patterned through a patterning process to form a second insulating layer disposed on the first conductive layer and a second conductive layer disposed on the second insulating layer.

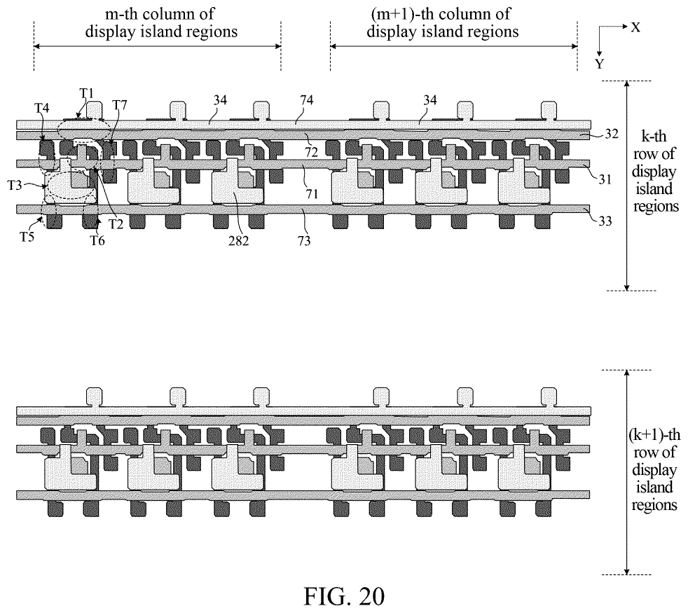

FIG. 20 is a schematic view of the display substrate after a second conductive layer is formed in FIG. 18. In some examples, as shown in FIG. 20, the second conductive layer of a single display island region may include at least a first initial signal line 34 and second electrode plates 282 of the storage capacitors of the three first pixel circuits. The second conductive layer of the first line region between display island regions adjacent in the first direction X may include at least a first initial connection line 74. The description of the second conductive layer of the display substrate of the present example may refer to the description of the foregoing embodiments and therefore will not be repeated here.
(2-5) A third insulating layer and a third conductive layer are formed. In some examples, a third insulation thin film is deposited on the base substrate on which the aforementioned patterns are formed, and the third insulation thin film is patterned through a patterning process to form a third insulation layer. The third insulating layer may be provided with a plurality of vias. The description of the third insulating layer of the present example may refer to the description of the foregoing embodiments, and will not be repeated here.

In some examples, a third conductive thin film is deposited on the base substrate on which the above-mentioned patterns are formed, and the third conductive thin film is patterned through a patterning process to form a third conductive layer disposed on the third insulating layer.

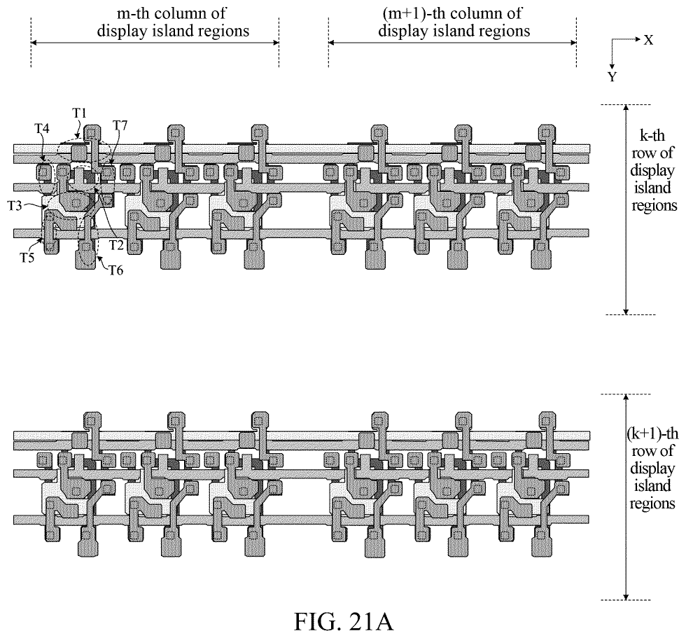

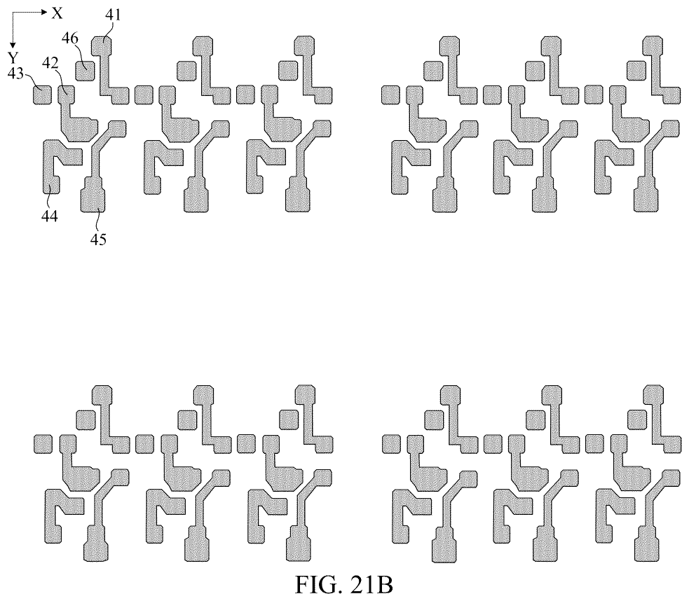

FIG. 21A is a schematic diagram of the display substrate after a third conductive layer is formed in FIG. 18. FIG. 21B is a schematic diagram of a third conductive layer in FIG. 21A. In some examples, as shown in FIGS. 21A and 21B, the third conductive layer of a single display island region of the first display region may include at least a first connection electrode 41, a second connection electrode 42, a third connection electrode 43, a fourth connection electrode 44, a fifth connection electrode 45, and a sixth connection electrode 46. The description of the third conductive layer of the present example may refer to the description of the foregoing embodiments, and will not be repeated here.
(2-6) Forming a fourth insulation layer and a fifth insulation layer. In some examples, a fourth insulating thin film is deposited on the base substrate on which the above-mentioned structures are formed, then a fifth insulating thin film is coated, and the fifth insulating thin film and the fourth insulating thin film are patterned through a patterning process to form a fourth fifth insulating layer and a fifth insulating layer. The fifth insulating layer and the fourth insulating layer may be provided with a plurality of vias.

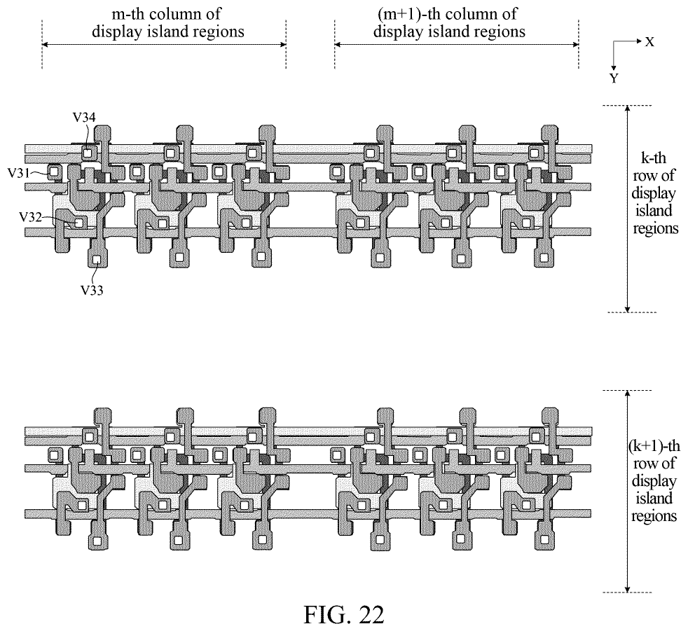

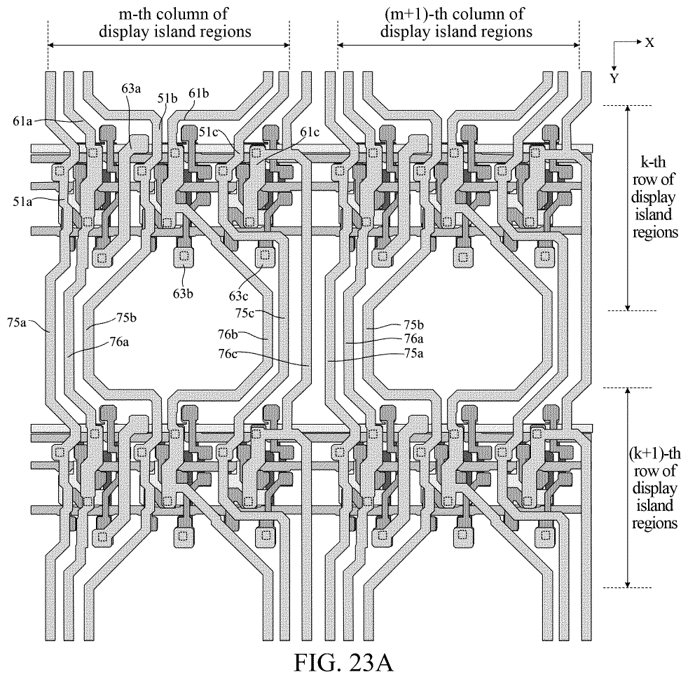

FIG. 22 is a schematic diagram of the display substrate after a fifth insulating layer is formed in FIG. 17. In some examples, the plurality of vias of the fifth insulating layer of a single display island region may include at least a thirty-first via V31, a thirty-second via V32, a thirty-third via V33, and a thirty-fourth via V34.

In some examples, an orthographic projection of the thirty-first via V31 on the base substrate may be within a range of an orthographic projection of the third connection electrode 43 on the base substrate. The fifth insulating layer and the fourth insulating layer in the thirty-first via V31 can be removed to expose a portion of a surface of the third connection electrode 43. The thirty-first via V31 may be configured so that a data line formed subsequently is connected to the third connection electrode 43 through the via.

In some examples, an orthographic projection of the thirty-second via V32 on the base substrate may be within a range of an orthographic projection of the fourth connection electrode 44 on the base substrate. The fifth insulating layer and the fourth insulating layer in the thirty-second via V32 may be removed to expose a portion of a surface of the fourth connection electrode 44. The thirty-second via V32 may be configured so that a second power supply connection line formed subsequently is connected to the fourth connection electrode 44 through the via.

In some examples, an orthographic projection of the thirty-third via V33 on the base substrate may be within a range of an orthographic projection of the fifth connection electrode 45 on the base substrate. The fifth insulating layer and the fourth insulating layer in the thirty-third via V33 can be removed to expose a portion of a surface of the fifth connection electrode 45. The thirty-third via V33 may be configured so that a second anode connection electrode formed subsequently is connected to the fifth connection electrode 45 through the via.

In some examples, an orthographic projection of the thirty-fourth via V34 on the base substrate may be within a range of an orthographic projection of the sixth connection electrode 46 on the base substrate. The fifth insulating layer and the fourth insulating layer in the thirty-fourth via V34 may be removed to expose a portion of a surface of the sixth connection electrode 46. The thirty-fourth via V34 may be configured so that a second power supply connection line formed subsequently is connected to the sixth connection electrode 46 through the via.
(2-7) The fourth conductive layer is formed. In some examples, a fourth conductive thin film is deposited on the base on which the aforementioned patterns are formed, and the fourth conductive thin film is patterned through a patterning process to form a fourth conductive layer disposed on the fifth insulating layer.

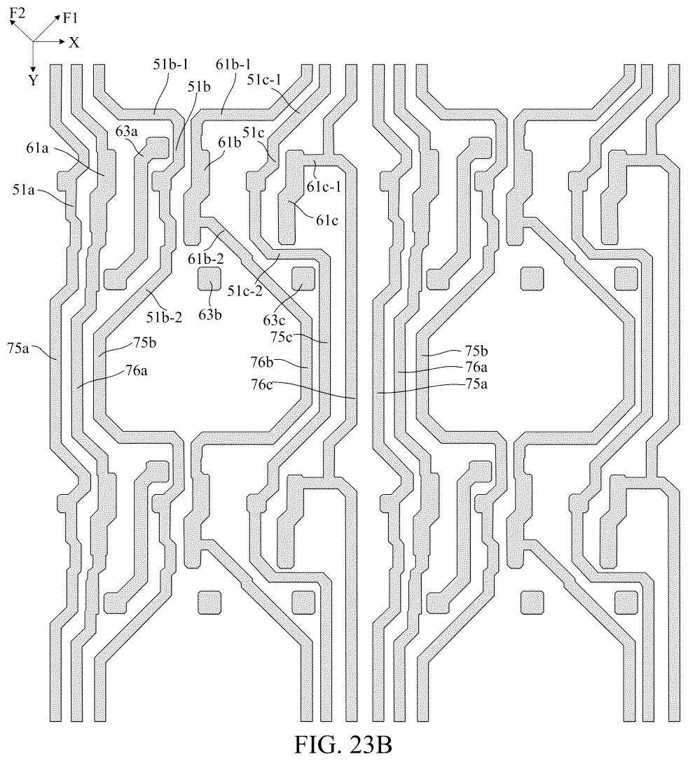

FIG. 23A is a schematic diagram of the display substrate after a fourth conductive layer is formed in FIG. 18. FIG. 23B is a schematic diagram of a fourth conductive layer in FIG. 23A. In some examples, as shown in FIGS. 23A and 23B, the fourth conductive layer of a single display island region of the first display region may include at least three data lines (e.g. including data lines 51a, 51b and 51c), three second power supply connection lines (e.g. including second power supply connection lines 61a, 61b and 61c), and three second anode connection electrodes (e.g. including second anode connection electrodes 63a, 63b and 63c).

In some examples, the data lines 51a, 51b and 51c may be arranged sequentially in the first direction X. The data line 51a may be substantially in a shape of a bending line in which a main portion extends in the second direction Y. The data line 51a may be electrically connected to the third connection electrode 43 of a first first pixel circuit through the thirty-first via V31 to be configured to provide a data signal to a first electrode of the fourth transistor T4 of the first first pixel circuit.

In some examples, the data line 51b may be substantially in a shape of a bending line in which a main portion extends in the second direction Y. The data line 51b may be configured to provide a data signal to a first electrode of the fourth transistor of a second first pixel circuit. The data line 51b may be provided with a first data connection portion 51b-1 on a side close to a previous row of display island regions, and the first data connection portion 51b-1 may extend at least in the first direction X. The first data connection portion 51b-1 may extend toward a direction close to the data line 51a in the first direction X. The first data connection portion 51b-1 and the data line 51b may be of an interconnected integral structure.

In some examples, the data line 51b may be provided with a second data connection portion 51b-2 on a side close to a next row of display island regions and the second data connection portion 51b-2 may extend in a third direction F1. The third direction F1 may intersect both the first direction X and the second direction Y. For example, the clockwise angle between the third direction F1 and the first direction X may be approximately 40 to 60 degrees, for example, may be approximately 45 degrees. The second data connection portion 51b-2 and the data line 51b may be of an interconnected integral structure.

In some examples, the data line 51c may be substantially in a shape of a bending line in which a main portion extends in the second direction Y. The data line 51c may be configured to provide a data signal to a first electrode of the fourth transistor of the third first pixel circuit. The data line 51c may be provided with a third data connection portion 51c-1 on a side close to a previous row of display island regions, and the third data connection portion 51c-1 may extend in the third direction F1 towards a side away from the data line 51c. The third data connection portion 51c-1 and the data line 51c may be of an interconnected integral structure.

In some examples, the data line 51c may be provided with a fourth data connection portion 51c-2 on a side close to a next row of display island regions. The fourth data connection portion 51c-2 may extend at least in the first direction X. The fourth data connection portion 51c-2 may extend in a direction away from the data line 51b in the first direction X. The fourth data connection portion 51c-2 and the data line 51c may be of an interconnected integral structure.

In some examples, the second power supply connection lines 61a, 61b and 61c may be sequentially arranged in the first direction X. The second power supply connection line 61a may be located between the data lines 51a and 51b, the second power supply connection line 61b may be located between the data lines 51b and 51c, and the second power supply connection line 61c may be located at a side of the data line 51c away from the data line 51b. In the display island region, the second power supply connection lines and the data lines can be arranged at intervals.

In some examples, the second power supply connection line 61a may be substantially in a shape of a bending line in which a main portion extends in the second direction Y. The extension direction of the second power supply connection line 61a and the extension direction of the data line 51a may be substantially the same. The second power supply connection line 61a may be electrically connected to the fourth connection electrode 44 in the first first pixel circuit through the thirty-second via V32, and may also be electrically connected to the sixth connection electrode 46 in the first first pixel circuit through the thirty-fourth via V34. The second power supply connection line 61a may be configured to provide a first voltage signal to the first first pixel circuit.

In some examples, the second power supply connection line 61b may be substantially in a shape of a bending line in which a main portion extends in the second direction Y. The extension direction of the second power supply connection line 61b and the extension direction of the data line 51b may be substantially the same. The second power supply connection line 61b may be configured to provide a first voltage signal to the second first pixel circuit.

In some examples, the second power supply connection line 61b may be provided with a first power supply extension portion 61b-1 on a side close to a previous row of display island regions, and the first power supply extension portion 61b-1 may extend at least in the first direction X. The first power supply extension portion 61b-1 may extend toward a side close to the data line 51c in the first direction X. The first data connection portion 51b-1 of the data line 51b and the first power supply extension portion 61b-1 may extend in opposite directions in the first direction X. The first power supply extension portion 61b-1 and the second power supply connection line 61b may be of an interconnected integral structure.

In some examples, the second power supply connection line 61b may be provided with a second power supply extension portion 61b-2 on a side close to a next row of display island regions. The second power supply extension portion 61b-2 may extend in a fourth direction F2. The fourth direction F2 may intersect both the first direction X and the second direction Y. For example, the clockwise angle between the fourth direction F2 and the first direction X may be approximately 120 degrees to 150 degrees, for example, may be approximately 135 degrees. The fourth direction F2 and the third direction F1 may intersect, for example, the fourth direction F2 may be perpendicular to the third direction F1. The second power supply extension portion 61b-2 may extend towards the fourth direction F2 along a side close to the data line 51c. The second power supply extension portion 61b-2 and the second power supply connection line 61b may be of an interconnected integral structure.

In some examples, the second power supply connection line 61c may be substantially in a shape of a bending line in which a main portion extends in the second direction Y. The extension direction of the second power supply connection line 61c and the extension direction of the data line 51c may be substantially the same. The second power supply connection line 61c may be configured to provide a first voltage signal to the third first pixel circuit.

In some examples, the second power supply connection line 61c may be provided with a third power supply extension portion 61c-1 on a side away from the data line 51c. The third power supply extension portion 61c-1 may extend in the first direction X toward a side away from the data line 51c. The third power supply extension portion 61c-1 and the second power supply connection line 61c may be of an interconnected integral structure.

In some examples, the second anode connection electrode 63a may be substantially in a shape of a bending line in which a main portion extends in the second direction Y. The second anode connection electrode 63a may be electrically connected to the fifth connection electrode 45 through the thirty-third via V33. In this example, the electrical connection of the first first pixel circuit and the first first light emitting element can be achieved through the second anode connection electrode 63a. In this example, the position of the first light emitting element can be changed by adjusting the shape and position of the second anode connection electrode 63a.

In some examples, the shapes of the second anode connection electrodes 63b and 63c may be substantially the same, for example, they may both be substantially rectangular. The second anode connection electrode 63b may be electrically connected to the sixth transistor of the second first pixel circuit so as to subsequently achieve the electrical connection of the second first pixel circuit to the second first light emitting element. The second anode connection electrode 63c may be electrically connected to the sixth transistor of the third first pixel circuit so as to subsequently achieve the electrical connection of the third first pixel circuit to the third first light emitting element.

In some examples, the fourth conductive layer of the second line region between display island regions adjacent in the second direction Y may include at least a plurality of first power supply connection lines (e.g. including first power supply connection lines 76a, 76b, and 76c), a plurality of data connection lines (e.g. including data connection lines 75a, 75b, and 75c). The plurality of data connection lines and the plurality of first power supply connection lines can be arranged at intervals. The data connection lines 75a, 75b, and 75c, and the first power supply connection lines 76a, 76b, and 76c may be substantially in a shape of a straight line extending in the second direction Y.

In some examples, three first power supply connection lines and three data connection lines may be arranged within a second line region. For example, the second line region between the m-th column of display island regions and the (m+1)-th column of display island regions may include a first power supply connection line 76b connected to a second column of first pixel circuits in the m-th column of display island regions, a data connection line 75c and a first power supply connection line 76c connected to a third column of first pixel circuits in the m-th column of display island regions, a data connection line 75a and a first power supply connection line 76a connected to a first column of first pixel circuits in the (m+1)-th column of display island regions, and a data connection line 75b connected to a second column of first pixel circuits in the (m+1)-th column of display island regions. The first power supply connection line 76b, the data connection line 75c, the first power supply connection line 76c, the data connection line 75a, the first power supply connection line 76a, and the data connection line 75b in the second line region may be arranged sequentially along the first direction X.

In some examples, the data lines 51a in display island regions adjacent in the second direction Y may be connected by the data connection line 75a. A first end of the data connection line 75a may be connected to the data line 51a in the display island region in the k-th row and the m-th column, and a second end thereof may be connected to the data line 51a in the display island region in the (k+1)-th row and the m-th column. The data line 51a and the data connection line 75a may be of an interconnected integral structure.

In some examples, the data lines 51b in display island regions adjacent in the second direction Y may be connected by the data connection line 75b. A first end of the data connection line 75b may be connected to the second data connection portion 51b-2 of the data line 51b in the display island region in the k-th row and the m-th column, and a second end thereof may be connected to the first data connection portion 51b-1 of the data line 51b in the display island region in the (k+1)-th row and the m-th column. The data line 51b and the data connection line 75b may be of an interconnected integral structure.

In some examples, the data lines 51c in display island regions adjacent in the second direction Y may be connected by the data connection line 75c. A first end of the data connection line 75c may be connected to the fourth data connection portion 51c-2 of the data line 51c in the display island region in the k-th row and the m-th column, and a second end thereof may be connected to the third data connection portion 51c-1 of the data line 51c in the display island region in the (k+1)-th row and the m-th column. The data line 51c and the data connection line 75c may be of an interconnected integral structure.

In some examples, the second power supply connection lines 61a in display island regions adjacent in the second direction Y may be connected through the first power supply connection line 76a. A first end of the first power supply connection line 76a may be connected to a second power supply connection line 61a in the display island region in the k-th row and m-th column, and a second end thereof may be connected to a second power supply connection line 61a in the display island region in the (k+1)-th row and the m-th column. The second power supply connection line 61a and the first power supply connection line 76a may be of an interconnected integral structure.

In some examples, the second power supply connection lines 61b in display island regions adjacent in the second direction Y may be connected through the first power supply connection line 76b. A first end of the first power supply connection line 76b may be connected to the second power supply extension portion 61b-2 of the second power supply connection line 61b in the display island region in the k-th row and the m-th column and a second end thereof may be connected to the first power supply extension portion 61b-1 of the second power supply connection line 61b in the display island region in the (k+1)-th row and the m-th column. The second power supply connection line 61b and the first power supply connection line 76b may be of an interconnected integral structure.

In some examples, the second power supply connection lines 61c in display island regions adjacent in the second direction Y may be connected through the first power supply connection line 76c. The first power supply connection line 76c may extend from the second line region to the first line region between display island regions adjacent in the first direction X. The first power supply connection line 76c may be in a shape of a bending line in which a main portion extends in the second direction Y. A portion of the first power supply connection line 76c in the second line region may be in a shape of a straight line extending in the second direction Y. The first power supply connection line 76c may be connected to the third power supply extension portion 61c-1 of the second power supply connection line 61c in the first line region. The first power supply connection line 76c and the second power supply connection line 61c may be of an interconnected integral structure.

The data line of the present example can be connected to the data connection line by means of the data connection portions with different extension directions, and the second power supply connection line can be connected to the first power supply connection line by means of the power supply extension portions with different extension directions, which can facilitate smoothing the edge of the display island region and improve the diffraction of the display substrate.
(2-8) A sixth insulation layer is formed. In some examples, a sixth insulating thin film is coated on the base on which the aforementioned patterns are formed, and the sixth insulating thin film is patterned through a patterning process to form a sixth insulating layer.

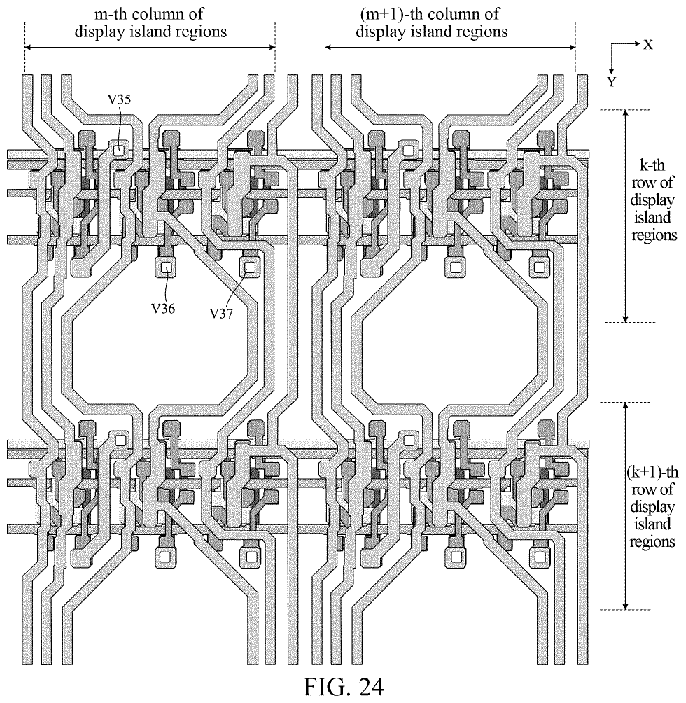

FIG. 24 is a schematic view of a display substrate after a sixth insulation layer is formed in FIG. 18. In some examples, the plurality of vias of the sixth insulating layer of a single display island region may include at least a thirty-fifth via V35, a thirty-sixth via V36, and a thirty-seventh via V37.

In some examples, an orthographic projection of the thirty-fifth via V35 on the base substrate may be within a range of an orthographic projection of the second anode connection electrode 63a on the base substrate. The sixth insulating layer in the thirty-fifth via V35 may be removed to expose a portion of a surface of the second anode connection electrode 63a. The thirty-fifth via V35 may be configured so that an anode of a first first light emitting element formed subsequently is connected to the second anode connection electrode 63a through the via

In some examples, an orthographic projection of the thirty-sixth via V36 on the base substrate may be within a range of an orthographic projection of the second anode connection electrode 63b on the base substrate. The sixth insulating layer in the thirty-sixth via V36 may be removed to expose a portion of a surface of the second anode connection electrode 63b. The thirty-sixth via V36 may be configured so that an anode of a first first light emitting element formed subsequently is connected to the second anode connection electrode 63b through the via.

In some examples, an orthographic projection of the thirty-seventh via V37 on the base substrate may be within a range of an orthographic projection of the second anode connection electrode 63c on the base substrate. The sixth insulating layer in the thirty-seventh via V37 may be removed to expose a portion of a surface of the second anode connection electrode 63c. The thirty-seventh via V37 may be configured so that an anode of a first first light emitting element formed subsequently is connected to the second anode connection electrode 63c through the via.

In some examples, after the formation of the sixth insulating layer, the first light transmitting region may include a base substrate, a first insulating layer, a second insulating layer, a third insulating layer, a fourth insulating layer, a fifth insulating layer, and a sixth insulating layer disposed on the base substrate sequentially. The first line region may include a base substrate, a first insulating layer, a first conductive layer (e.g. including a first scan connection line 71, a second scan connection line 72, and a light emitting control connection line 73), a second insulating layer, a second conductive layer (e.g. including a first initial connection line 74), a third insulating layer, a fourth insulating layer, a fifth insulating layer, a fourth conductive layer (e.g. including a first power supply connection line 76c), and a sixth insulating layer sequentially arranged on the base substrate. The second line region may include a base substrate, a first insulating layer, a second insulating layer, a third insulating layer, a fourth insulating layer, a fifth insulating layer, a fourth conductive layer (including, for example, data connection lines 75a, 75b and 75c, first power supply connection lines 76a, 76b and 76c) and a sixth insulating layer arranged on the base substrate sequentially.

In this example, a first signal line connecting first pixel circuits in adjacent display island regions may include a first scan connection line, a second scan connection line and a light emitting control connection line located in the first conductive layer, and a first initial connection line located in the second conductive layer. A second signal line connecting first pixel circuits in adjacent display island regions may include a first power supply connection line and a data connection line located in the fourth conductive layer.

In other examples, a second light transmitting region may be formed between display island regions adjacent along the first direction X, for example, the edge of the second light transmitting region may be defined by the first scan connection line, the light emitting control connection line, the first power supply connection line 76c, and the data line 51a, and a smooth edge of the second light transmitting region may be achieved by bending these lines to improve the diffraction condition.
(2-9) An anode layer is formed. In some examples, an anode thin film is deposited on the base substrate on which the aforementioned patterns are formed, and the anode thin film is patterned through a patterning process to form an anode layer.

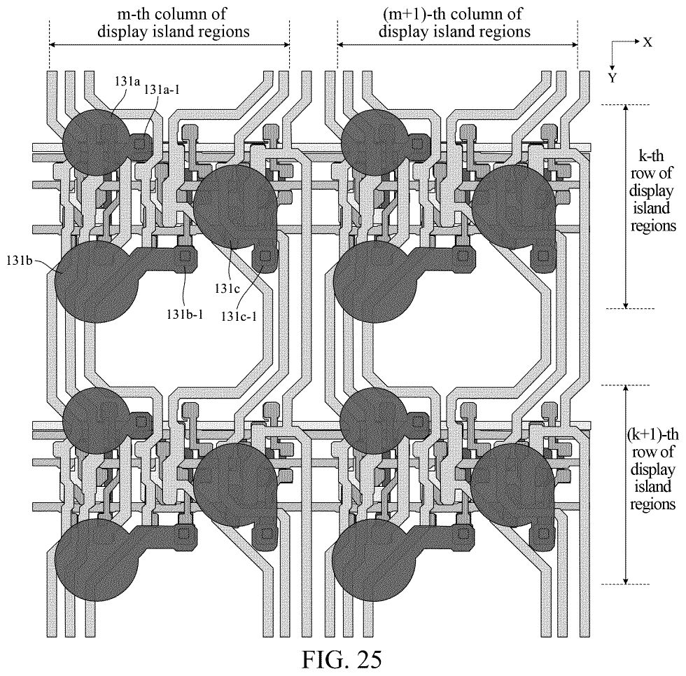

FIG. 25 is a schematic diagram of the display substrate after an anode layer is formed in FIG. 18. In some examples, as shown in FIG. 25, the anode layer of a single display island region may include at least three anodes (e.g. including anodes 131a, 131b and 131c).

In some examples, a side of the anode 131a close to the anode 131c may be provided with an anode connection block 131a-1. The anode connection block 131a-1 may be provided in the first first pixel circuit. A first end of the anode connection block 131a-1 is connected to the anode 131a and a second end thereof extends in the first direction X towards a direction away from the anode 131a. The anode connection block 131a-1 may be electrically connected to the second anode connection electrode 63a through the thirty-fifth via V35. The anode connection block 131a-1 and the anode 131a may be of an interconnected integral structure.

In some examples, a side of the anode 131b close to the anode 131c may be provided with an anode connection block 131b-1. At least part of the anode connection block 131b-1 may be disposed in the second first pixel circuit. A first end of the anode connection block 131b-1 is connected to the anode 131b and a second end thereof extends towards a direction away from the anode 131b in the first direction X. The anode connection block 131b-1 may be electrically connected to the second anode connection electrode 63b through the thirty-sixth via V36. The anode connection block 131b-1 and the anode 131b may be of an interconnected integral structure.

In some examples, a side of the anode 131c close to the anode 131b may be provided with an anode connection block 131c-1. The anode connection block 131c-1 may be provided in the third first pixel circuit. A first end of the anode connection block 131c-1 is connected to the anode 131c and a second end thereof extends in the second direction Y towards a direction away from the anode 131c. The anode connection block 131c-1 may be electrically connected to the second anode connection electrode 63c through the thirty-seventh via V37. The anode connection block 131c-1 and the anode 131c may be of an interconnected integral structure.
(2-10) A pixel define layer, an organic light emitting layer, a cathode layer and an encapsulation layer are formed sequentially. The preparation process of the pixel define layer, the organic light emitting layer, the cathode layer and the encapsulation layer of the present example can be referred to the foregoing embodiments, and will not be repeated here.

The first signal line and the second signal line of the display substrate in this embodiment are made of a metal material, which can reduce the material cost and the mask cost of using the transparent conductive layer, can reduce the lateral or longitudinal display defect due to the large resistance of the first signal line and the second signal line, and can also simplify the process and avoid the excessive opening process. Furthermore, the plurality of first signal lines (for example, including the first scan connection line, the second scan connection line, the light emitting control connection line and the first initial connection line) of the present example are in a shape of a straight line extending along the first direction X, and the plurality of second signal lines (for example, including the first power supply connection line and the data connection line) are in a shape of a straight line extending along the second direction Y, which can save occupied space, facilitate an increase in the light transmittance of the light transmitting region and reduce the light diffraction effect.

The display substrate according to the present embodiment, by centrally arranging a plurality of first pixel circuits and a plurality of first light emitting elements in the display island region, can reduce the quantities of isolated islands and slits, effectively reduce the light diffraction effect, and facilitate smooth processing on the edge of the display island region.

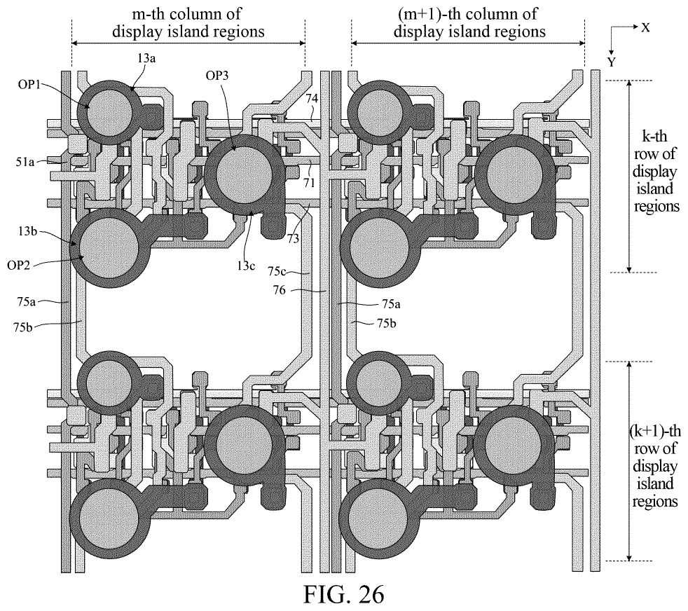

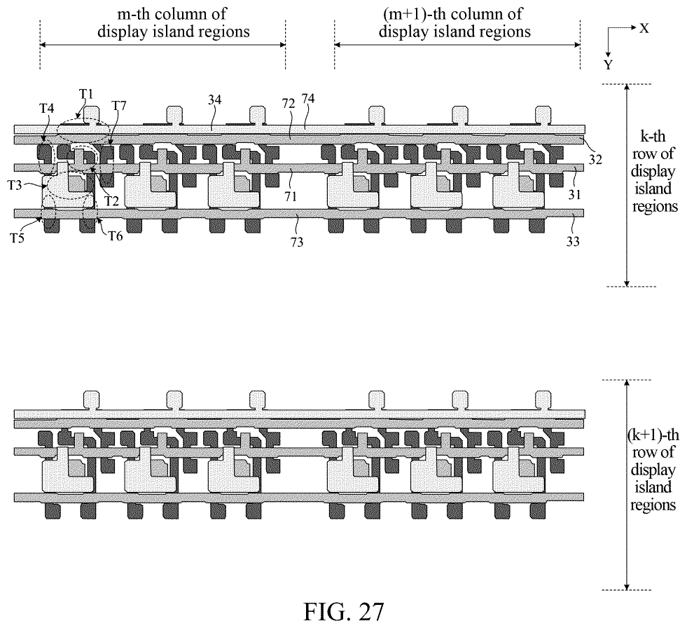

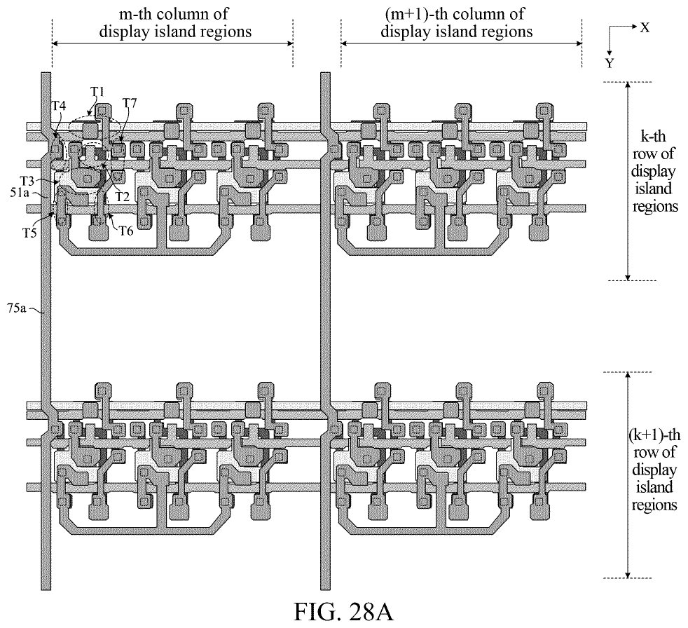

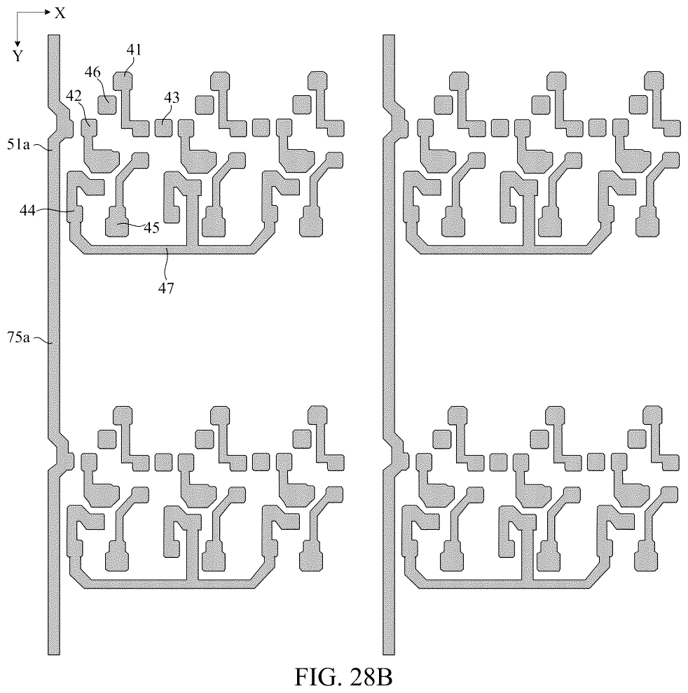

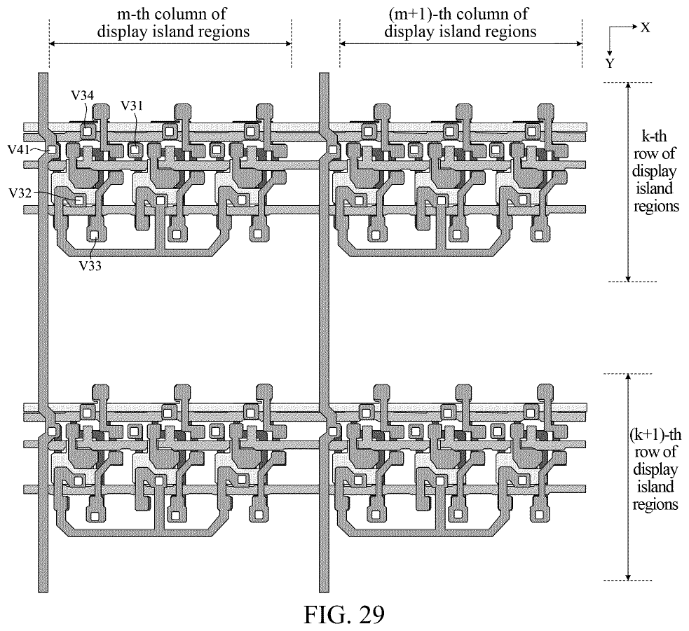

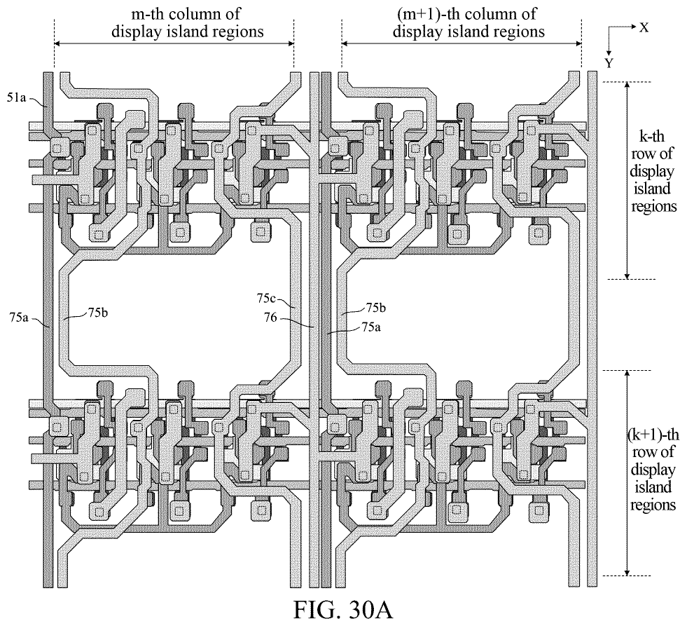

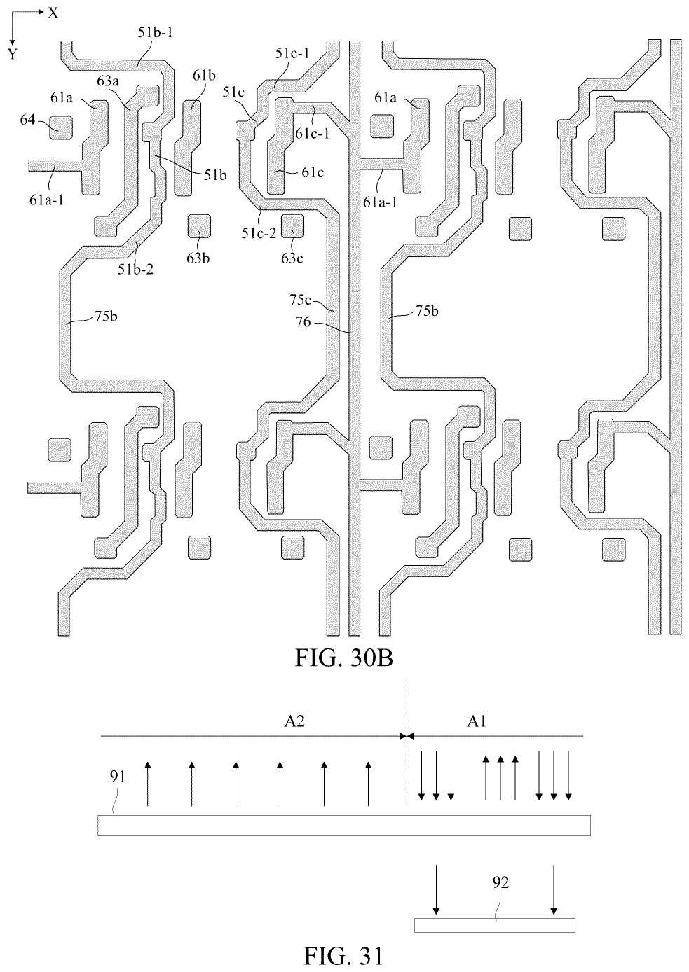

FIG. 26 is another schematic partial top view of the region S2 in FIG. 17A. Four display island regions A11 arranged in a 2×2 array are illustrated in FIG. 26. FIG. 27 is a schematic view of the display substrate after a second conductive layer is formed in FIG. 26. FIG. 28A is a schematic diagram of the display substrate after a third conductive layer is formed in FIG. 26. FIG. 28B is a schematic diagram of a third conductive layer in FIG. 28A. FIG. 29 is a schematic view of a display substrate after a fifth insulation layer is formed in FIG. 26. FIG. 30A is a schematic diagram of the display substrate after a fourth conductive layer is formed in FIG. 26. FIG. 30B is a schematic diagram of a fourth conductive layer in FIG. 30A.

In some examples, in a direction perpendicular to the display substrate, the circuit structure layer of the first display region may include a semiconductor layer, a first conductive layer, a second conductive layer, a third conductive layer, and a fourth conductive layer that are sequentially disposed on the base substrate. A first insulating layer may be provided between the semiconductor layer and the first conductive layer, a second insulating layer may be provided between the first conductive layer and the second conductive layer, a third insulating layer may be provided between the second conductive layer and the third conductive layer, a fourth insulating layer and a fifth insulating layer may be provided between the third conductive layer and the fourth conductive layer, and a sixth insulating layer may be provided on a side of the fourth conductive layer away from the base substrate. Patterns of the semiconductor layer, the first conductive layer, the second conductive layer and the third insulating layer of the present example may be referred to the embodiment shown in FIG. 18 and therefore will not be repeated herein.

In some examples, as shown in FIGS. 28A and 28B, the third conductive layer of a single display island region of the first display region may include at least a first connection electrode 41, a second connection electrode 42, a third connection electrode 43, a fourth connection electrode 44, a fifth connection electrode 45, a sixth connection electrode 46, a seventh connection electrode 47, and a data line (including, for example, a data line 51a). Quantities of the first connection electrodes 41, the second connection electrodes 42, the fourth connection electrodes 44, the fifth connection electrodes 45, and the sixth connection electrodes 46 are all three, and the quantity of the third connection electrodes 43 is two. The third conductive layer of a single second line region between display island regions adjacent in the second direction Y may include at least one data connection line (e.g. data connection line 75a). The description of the first connection electrode 41, the second connection electrode 42, the third connection electrode 43, the fifth connection electrode 45, and the sixth connection electrode 46 of the present example may refer to the description of the foregoing embodiments, and therefore will not be repeated here.

In some examples, as shown in FIGS. 27, 28A and 28B, the three fourth connection electrodes 44 of a single display island region may all be connected to the seventh connection electrode 47. The seventh connection electrode 47 may be substantially E-shaped. The seventh connection electrode 47 may be located on a same side of the three fourth connection electrodes 44 in the second direction Y. A first end of the seventh connection electrode 47 may be electrically connected with a first fourth connection electrode 44 to achieve the electrical connection between the seventh connection electrode 47 and the fifth transistor and the storage capacitor of the first first pixel circuit, a second end of the seventh connection electrode 47 may be electrically connected with a second fourth connection electrode 44 to achieve the electrical connection between the seventh connection electrode 47 and the fifth transistor and the storage capacitor of the second first pixel circuit, and the third end of the seventh connection electrode 47 may be electrically connected with a third fourth connection electrode 44 to achieve the electrical connection between the seventh connection electrode 47 and the fifth transistor and the storage capacitor of the third first pixel circuit. The seventh connection electrode 47 and the three fourth connection electrodes 44 may be of an interconnected integral structure.

In some examples, as shown in FIGS. 28A and 28B, the data line 51a may be in a shape of a bending line segment in which a main portion extends in the second direction Y. The data line 51a may be electrically connected to the first region of the fourth active layer of the fourth transistor of the first first pixel circuit through vias opened in the third insulating layer, the second insulating layer and the first insulating layer. The data connection line 75a may be substantially in a shape of a straight line extending in the second direction Y. The data lines 51a in display island regions adjacent in the second direction Y may be connected by the data connection line 75a. For example, a first end of the data connection line 75a in the second line region between the m-th column of display island regions and the (m−1)-th column of display island regions may be connected to the data line 51a in the display island region in the m-th column and k-th row, and a second end thereof may be connected to the data line 51a in the display island region in the m-th column and (k+1)-th row. The data line 51a and the data connection line 75a may be of an interconnected integral structure.

In some examples, as shown in FIG. 29, the plurality of vias of the fifth insulating layer of a single display island region may include at least a thirty-first via V31, a thirty-second via V32, a thirty-third via V33, a thirty-fourth via V34, and a forty-first via V41. The description of the thirty-first via V31, the thirty-second via V32, the thirty-third via V33, and the thirty-fourth via V34 can refer to the description of the foregoing embodiments, and therefore will not be repeated here.

In some examples, as shown in FIGS. 29 and 28A, an orthographic projection of the forty-first via V41 on the base substrate may be within a range of an orthographic projection of the data line 51a on the base substrate. The fifth insulating layer and the fourth insulating layer in the forty-first via V41 can be removed to expose a portion of a surface of the data line 51a. The forty-first via V31 may be configured so that a third conductive block formed subsequently is connected to the data line 51a through the via.

In some examples, as shown in FIGS. 30A and 30B, the fourth conductive layer of a single display island region may include at least two data lines (e.g. including data lines 51b and 51c), three second power supply connection lines (e.g. including second power supply connection lines 61a, 61b and 61c), three second anode connection electrodes (e.g. including second anode connection electrodes 63a, 63b and 63c), and one third conductive block 64.

In some examples, as shown in FIGS. 26 to 30B, the third conductive block 64 may be substantially in a shape of a rectangle, for example, may be in a shape of a rounded rectangle. The third conductive block 64 may be electrically connected to the data line 51a through the forty-first via V41. The third conductive block 64 facilitates the reduction of the resistance of the data line 51a by being connected in parallel with the data line 51a. Moreover, homogenization of the pattern of the film is facilitated by the provision of the third conductive block.

In some examples, as shown in FIGS. 26 to 30B, the second power supply connection lines 61a, 61b and 61c may all be in a shape of a bending line in which a main portion extends in the second direction Y. The second power supply connection line 61a may be electrically connected to the fourth connection electrode 44 through the thirty-second via V32 located in the first first pixel circuit, and may be electrically connected to the sixth connection electrode 46 through the thirty-fourth via V34 located in the first first pixel circuit. The second power supply connection line 61a may be electrically connected to the fourth connection electrode and the sixth connection electrode in the second first pixel circuit. The second power supply connection line 61c may be electrically connected to the fourth connection electrode and the sixth connection electrode in the third first pixel circuit.

In some examples, as shown in FIGS. 30A and 30B, the second power supply connection line 61a may be provided with a fourth power supply extension portion 61a-1 on a side close to the data line 51a. The fourth power supply extension portion 61a-1 may extend in the first direction X toward a side of the data line 51. The fourth power supply extension portion 61a-1 and the second power supply connection line 61a may be of an interconnected integral structure. The second power supply connection line 61c may be provided with a third power supply extension portion 61c-1 on a side away from the data line 51c. The third power supply extension portion 61c-1 may extend in the first direction X toward a side away from the data line 51c. The third power supply extension portion 61c-1 and the second power supply connection line 61c may be of an interconnected integral structure.

In some examples, as shown in FIGS. 30A and 30B, the fourth conductive layer of a single second line region between display island regions adjacent in the second direction Y may include at least one first power supply connection line (e.g. first power supply connection line 76), two data connection lines (e.g. including data connection lines 75b and 75c). The first power supply connection line 76 and the data connection lines 75b and 75c may be substantially in a shape of a straight line extending in the second direction Y.

In some examples, as shown in FIGS. 26, 30A, and 30B, the second line region between the m-th column of display island regions and the (m+1)-th column of display island regions may include a data connection line 75c electrically connected to a third column of first pixel circuits in the m-th column of display island regions, a data connection line 75b electrically connected to a second column of first pixel circuits in the (m+1)-th column of display island regions, a data connection line 75a electrically connected to a first column of first pixel circuits in the (m+1)-th column of display island regions, and a first power supply connection line 76. The data connection line 75c, the first power supply connection line 76, the data connection line 75a and the data connection line 75b may be arranged sequentially in the first direction X. The first power supply connection line 76 may be connected to the third power supply extension portion 61c-1 of the second power supply connection line 61c in the m-th column of display island regions, and may be connected to the fourth power supply extension portion 61a-1 of the second power supply connection line 61a in the (m+1)-th column of display island regions. The first power supply connection line 76 and adjacent second power supply connection line 61c and second power supply connection line 61a may be of an interconnected integral structure.

In some examples, within a single display island region, lateral transmission of the first voltage signal is achieved using the fourth and seventh connection electrodes 44 and 47. Lateral transmission of the first voltage signal between adjacent display island regions is achieved using the first power supply connection line 76 and adjacent second power supply connection line 61a and second power supply connection line 61c. Longitudinal transmission of the first voltage signal between adjacent display island regions is achieved using the first power supply connection line 76. The first power supply connection line, the second power supply connection line, the fourth connection electrode and the seventh connection electrode in the present example can form a grid structure in mesh communication for transmitting the first voltage signal, which not only reduces the voltage drop of the first voltage signal, but also effectively improves the uniformity of the first voltage signal in the display substrate, effectively improves the display uniformity, and improves the display attribute and the display quality. Moreover, the second line region of the present example can be provided with only three data connection lines and one first power supply connection line, which can reduce the quantity of connection lines, thereby reducing the space occupied by the second line region and facilitating the improvement of the light transmittance of the first light transmitting region.

Rest of a structure of the display substrate according to this example may be referred to the description of the aforementioned embodiments, and thus will not be repeated here.

The present embodiment further provides a display substrate including: a first display region. The first display region includes a plurality of display island regions arranged in an array, and a light transmitting region located between adjacent display island regions. The light transmitting region includes a first light transmitting region located between display island regions adjacent in a second direction. At least one display island region of the plurality of display island regions and the first light transmitting region are alternately arranged in the second direction. The display island region includes a plurality of first pixel circuits and a plurality of first light emitting elements disposed on a base substrate. At least one first pixel circuit of the plurality of first pixel circuits is electrically connected with at least one first light emitting element of the plurality of first light emitting elements. At least one first pixel circuit is configured to drive the at least one first light emitting element to emit light. First pixel circuits in adjacent display island regions are connected by a plurality of first signal lines in a first direction, and the first pixel circuits in the adjacent display island regions are connected by a plurality of second signal lines in the second direction; the first direction intersects with the second direction.

In some exemplary embodiments, the first light transmitting region is located between a plurality of second signal lines in the first direction. For example, the plurality of second signal lines may include a first power supply connection line and a data connection line.

In some exemplary embodiments, the light transmitting region may further include a second light transmitting region. The second light transmitting region is located between display island regions adjacent along the first direction. The area of the first light transmitting region may be larger than the area of the second light transmitting region.

In some exemplary embodiments, the second light transmitting region is located between the plurality of first signal lines. For example, the plurality of first signal lines may include a first scan connection line, a second scan connection line, a light emitting control connection line, and a first initial connection line.

In some exemplary embodiments, at least one display island region of the plurality of display island regions includes: three first pixel circuits and three first light emitting elements. The three first pixel circuits and the three first light emitting elements are electrically connected in one-to-one correspondence, the three first pixel circuits are sequentially arranged along the first direction. The three first light emitting elements comprise: a first light emitting element emitting light of a first color, a first light emitting element emitting light of a second color and a first light emitting element emitting light of a third color. An orthographic projection of a light emitting region of the first light emitting element emitting light of the first color on the base substrate and an orthographic projection of a first pixel circuit to which the first light emitting element emitting light of the first color is connected on the base substrate at least partially overlap. An orthographic projection of a light emitting region of the first light emitting element emitting light of the second color on the base substrate and an orthographic projection of a first pixel circuit connected to the first light emitting element emitting light of the second color on the base substrate are not overlapped. An orthographic projection of a light emitting region of the first light emitting element emitting light of the third color on the base substrate overlaps at least partially with an orthographic projection of a first pixel circuit connected to the first light emitting element emitting light of the third color on the base substrate.

The structure of the display substrate of the present embodiment can be referred to the foregoing embodiments and is therefore not described here.

FIG. 31 is a schematic diagram of a display device according to at least one embodiment of the present disclosure. As shown in FIG. 31, an embodiment provides a display apparatus, which includes a display substrate 91 and a sensor 92 located on a light exit side of a light emitting structure layer away from the display substrate 91. The sensor 92 may be located on a side of a non-display surface of the display substrate 91. An orthographic projection of the sensor 92 on the display substrate 91 may be overlapped with a first display region A1.

In some exemplary implementations, the display substrate 91 may be a flexible OLED display substrate, a QLED display substrate, a Micro-LED display substrate or a Mini-LED display substrate. The display apparatus may be a product having an image (including a still image or a moving image, wherein the moving image may be a video) display function. For example, the display apparatus may be: displays, televisions, billboards, digital photo frames, laser printers with display function, telephones, mobile phones, picture screens, personal digital assistants (PDA), digital cameras, portable camcorders, viewfinders, navigators, vehicles, large-area walls, information inquiry equipment (such as business inquiry equipment in e-government, banks, hospitals, power departments, etc.), monitors, etc. As another example, the display apparatus may be any one of a micro-display, a VR device including a micro-display, or an AR device.

The drawings of the present disclosure only involve structures involved in the present disclosure, and other structures may refer to conventional designs. The embodiments of the present disclosure, i.e., features in the embodiments, may be combined with each other to obtain new embodiments if there is no conflict. Those of ordinary skills in the art should understand that modifications or equivalent replacements may be made to the technical solutions of the present disclosure without departing from the essence and scope of the technical solutions of the present disclosure, and shall all fall within the scope of the claims of the present disclosure.

1. A display substrate, comprising: a first display region, wherein:
the first display region comprises a plurality of display island regions arranged in an array, and a light transmitting region located between adjacent display island regions;
each display island region comprises a plurality of first pixel circuits and a plurality of first light emitting elements disposed on a base substrate, at least one first pixel circuit of the plurality of first pixel circuits is electrically connected with at least one first light emitting element of the plurality of first light emitting elements, the at least one first pixel circuit is configured to drive the at least one first light emitting element to emit light;
first pixel circuits in adjacent display island regions are connected by a plurality of first signal lines in a first direction, and the first pixel circuits in the adjacent display island regions are connected by a plurality of second signal lines in a second direction; the first direction is intersected with the second direction; and
materials of the plurality of second signal lines comprises a transparent conductive material, or materials of the plurality of first signal lines and the plurality of second signal lines each comprises a metal material.

2. The display substrate according to claim 1, wherein a film on which the plurality of second signal lines are located is located on a side of a film on which the plurality of first signal lines are located away from the base substrate.

3. The display substrate according to claim 1, wherein the materials of the plurality of first signal lines comprises a metal material, the materials of the plurality of second signal lines comprises a transparent conductive material, and the plurality of second signal lines are in a same layer.

4. The display substrate according to claim 3, wherein at least portion of the plurality of second signal lines are located in the light transmitting region.

5. The display substrate according to claim 3, wherein the light transmitting region comprises: a first light transmitting region located between display island regions adjacent along the second direction, and a second light transmitting region located between display island regions adjacent along the first direction; and an area of the first light transmitting region is larger than an area of the second light transmitting region.

6. The display substrate according to claim 1, wherein in a case that the materials of the plurality of first signal lines and the plurality of second signal lines each comprises a metal material,
the plurality of second signal lines are in a same layer, or at least one second signal line of the plurality of the second signal lines and the rest of the second signal lines are in different layers.

7. The display substrate according to claim 6, wherein the light transmitting region comprises at least: a first light transmitting region located between display island regions adjacent in the second direction; the display substrate further comprises: a first line region located between adjacent first light transmitting regions, wherein the first line region is communicated with the display island region; the plurality of second signal lines are located in the first line region.

8. The display substrate according to claim 6, wherein the plurality of second signal lines comprises a plurality of data connection lines for transmitting data signals to the plurality of first pixel circuits in the display island region, respectively, and at least one first power supply connection line for transmitting a first voltage signal to the plurality of first pixel circuits in the display island region.

9. The display substrate according to claim 8, wherein the plurality of first pixel circuits in the display island region are electrically connected to a same first power supply connection line.

10. The display substrate according to claim 8, wherein the plurality of first pixel circuits in the display island region are electrically connected to a plurality of first power supply connection lines, respectively, and the plurality of data connection lines and the plurality of first power supply connection lines are arranged at intervals.

11. The display substrate according to claim 8, wherein the plurality of first pixel circuits in the display island region are arranged sequentially along the first direction, and a data connection line connected to a first one of the plurality of first pixel circuits and data connection lines connected to the rest of the first pixel circuits are in different layers.

12. The display substrate according to claim 1, wherein at least one first signal line of the plurality of first signal lines and the rest of the first signal lines are in different layers.

13. The display substrate according to claim 12, wherein the plurality of first signal lines comprises: a first initial connection line for transmitting a first initial signal, a first scan connection line for transmitting a first scan signal, a second scan connection line for transmitting a second scan signal, and a light emitting control connection line for transmitting a light emitting control signal; and
wherein the first scan connection line, the second scan connection line and the light emitting control connection line are in a same layer.

14. The display substrate according to claim 1, wherein at least one display island region of the plurality of display island regions comprises three first pixel circuits and three first light emitting elements, the three first pixel circuits and the three first light emitting elements are electrically connected in one-to-one correspondence, the three first pixel circuits are sequentially arranged in the first direction.

15. The display substrate according to claim 14, wherein: the three first light emitting elements comprise: a first light emitting element that emits light of a first color, a first light emitting element that emits light of a second color, and a first light emitting element that emits light of a third color; and
the first light emitting element emitting light of the first color and the first light emitting element emitting light of the second color are arranged in a same column, the first light emitting element emitting light of the third color and the first light emitting element emitting light of the first color are arranged in different columns, and the first light emitting element emitting light of the first color, the first light emitting element emitting light of the second color and the first light emitting element emitting light of the third color are arranged in different rows.

16. The display substrate according to claim 15, wherein an area of a light emitting region of the first light emitting element emitting light of the second color is larger than an area of a light emitting region of the first light emitting element emitting light of the first color, and an area of a light emitting region of the first light emitting element emitting light of the third color is larger than an area of the light emitting region of the first light emitting element emitting light of the first color.

17. The display substrate according to claim 15, wherein an orthographic projection of a light emitting region of the first light emitting element emitting light of the first color on the base substrate and an orthographic projection of a first pixel circuit to which the first light emitting element emitting light of the first color is connected on the base substrate are at least partially overlapped;
an orthographic projection of a light emitting region of the first light emitting element emitting light of the second color on the base substrate and an orthographic projection of a first pixel circuit connected to the first light emitting element emitting light of the second color on the base substrate are not overlapped; and
an orthographic projection of a light emitting region of the first light emitting element emitting light of the third color on the base substrate is overlapped at least partially with an orthographic projection of a first pixel circuit connected to the first light emitting element emitting light of the third color on the base substrate.

18. The display substrate according to claim 17, wherein an overlapping area of a light emitting region of the first light emitting element emitting light of the third color and a first pixel circuit connected to the first light emitting element emitting light of the third color is larger than an overlapping area of a light emitting region of the first light emitting element emitting light of the first color and a first pixel circuit connected to the first light emitting element emitting light of the first color.

19. The display substrate according to claim 1, further comprising: a second display region located on at least one side of the first display region, wherein the second display region comprises a plurality of second pixel circuits and a plurality of second light emitting elements disposed on the base substrate, at least one second pixel circuit of the plurality of second pixel circuits is electrically connected with at least one second light emitting element of the plurality of second light emitting elements, and the at least one second pixel circuit is configured to drive the at least one second light emitting element to emit light.

20. A display apparatus, comprising: the display substrate according to claim 1, and a sensor located on a non-display side of the display substrate, wherein an orthographic projection of the sensor on the display substrate is overlapped with the first display region of the display substrate.

21-25. (canceled)
